(19) United States
(12) Patent Application Publication
(10) Pub. No.: US 2024/0079262 A1
(43) Pub. Date: Mar. 7, 2024

(54) SUPPORT STAGE, SUPPORT DEVICE, AND METHOD FOR MANUFACTURING SEMICONDUCTOR DEVICE

(71) Applicants: ROHM CO., LTD., Kyoto-shi, Kyoto (JP); LAPIS Semiconductor Co., Ltd., Yokohama-shi, Kanagawa (JP)

(72) Inventors: Hajime USHIO, Kyoto-shi (JP); Yuta MAKINO, Yokohama-shi (JP); Hirofumi SHIRAGASAWA, Yokohama-shi (JP)

(73) Assignees: ROHM CO., LTD., Kyoto-shi, Kyoto (JP); LAPIS Semiconductor Co., Ltd., Yokohama-shi, Kanagawa (JP)

(21) Appl. No.: 18/507,113

(22) Filed: Nov. 13, 2023

Related U.S. Application Data
(63) Continuation of application No. PCT/JP2022/016525, filed on Mar. 31, 2022.

(30) Foreign Application Priority Data
May 14, 2021 (JP) 2021-082788

(51) Int. Cl. H01L 21/683; H01L 21/04; H01L 21/304; H01L 21/67

(52) U.S. Cl. CPC H01L 21/6838; H01L 21/0445; H01L 21/304; H01L 21/67017

(57) ABSTRACT

A support stage includes a base portion, a support portion that is erected at a peripheral edge portion of the base portion and with which one surface of a wafer is to be come into contact, a suction groove that is provided at the support portion and to which a suction force with respect to the one surface is to be given, an ejecting hole that is provided in an inward portion of the base portion and by which a gas is to be ejected toward the one surface, and an exhaust hole that is provided in at least either one of the base portion and the support portion and by which a gas is to be discharged from a space between the base portion, the support portion, and the one surface.

### CROSS-REFERENCE TO RELATED APPLICATIONS

The present application is a bypass continuation of International Patent Application No. PCT/JP2022/016525, filed on Mar. 31, 2022, which claims priority to Japanese Patent Application No. 2021-082788 filed in the Japan Patent Office on May 14, 2021, and the entire disclosure of these applications are incorporated herein by reference.

### BACKGROUND

### 1. Field of the Disclosure

The present disclosure relates to a support stage.

### 2. Description of the Related Art

Japanese Patent Application Publication No. 2012-164839 discloses a support device having a holding portion that holds a wafer and a main body portion that is formed continuously with the holding portion so as to face the wafer.

### BRIEF DESCRIPTION OF THE DRAWINGS

FIG. 1 is a plan view showing a configuration example of a wafer.

FIG. 2 is a cross-sectional view along line II-II shown in FIG. 1.

FIG. 3 is a plan view showing a support stage according to a first embodiment.

FIG. 4 is a cross-sectional view along line IV-IV shown in FIG. 3.

FIG. 5 is a cross-sectional view along line V-V shown in FIG. 3.

FIG. 6 is a schematic view showing a configuration example of a support device.

FIG. 7 is a flowchart showing an example of a method for manufacturing a semiconductor device.

FIG. 8A is a schematic view showing a step of the method for manufacturing the semiconductor device.

FIG. 8B is a schematic view showing a step subsequent to that of FIG. 8A.

FIG. 8C is a schematic view showing a step subsequent to that of FIG. 8B.

FIG. 8D is a schematic view showing a step subsequent to that of FIG. 8C.

FIG. 8E is a schematic view showing a step subsequent to that of FIG. 8D.

FIG. 8F is a schematic view showing a step subsequent to that of FIG. 8E.

FIG. 8G is a schematic view showing a step subsequent to that of FIG. 8F.

FIG. 8H is a schematic view showing a step subsequent to that of FIG. 8G.

FIG. 8I is a schematic view showing a step subsequent to that of FIG. 8H.

FIG. 8J is a schematic view showing a step subsequent to that of FIG. 8I.

FIG. 9 is a graph showing a processing result of warpage in a case in which barometric pressure control is applied.

FIG. 10 is a graph showing a processing result of warpage in a case in which barometric pressure control is not applied.

FIG. 11 is a plan view showing a support stage according to a second embodiment.

FIG. 12 is a plan view showing a support stage according to a third embodiment.

FIG. 13 is a plan view showing a support stage according to a fourth embodiment.

FIG. 14 is a plan view showing a support stage according to a fifth embodiment.

FIG. 15 is a plan view showing a support stage according to a sixth embodiment.

FIG. 16 is a plan view showing a support stage according to a seventh embodiment.

FIG. 17 is a plan view showing a support stage according to an eighth embodiment.

FIG. 18 is a plan view showing a support stage according to a ninth embodiment.

FIG. 19 is a plan view showing a support stage according to a tenth embodiment.

FIG. 20 is a plan view showing a support stage according to an eleventh embodiment.

FIG. 21 is a plan view showing a support stage according to a twelfth embodiment.

FIG. 22 is a cross-sectional view along line XXII-XXII shown in FIG. 21.

FIG. 23 is a plan view showing a support stage according to a thirteenth embodiment.

FIG. 24 is a cross-sectional view along line XXIV-XXIV shown in FIG. 23.

FIG. 25 is a plan view showing a support stage according to a fourteenth embodiment.

FIG. 26 is a cross-sectional view along line XXVI-XXVI shown in FIG. 25.

FIG. 27 is a cross-sectional view along line XXVII-XXVII shown in FIG. 25.

FIG. 28 is a plan view showing another configuration example of the wafer shown in FIG. 1.

FIG. 29 is a cross-sectional enlarged view of a main portion of a functional device shown in FIG. 28.

FIG. 30 is a plan view showing another configuration example of the support device shown in FIG. 6.

FIG. 31A is a schematic view showing an example of a step performed for a wafer having a mountain-fold-shaped warpage.

FIG. 31B is a schematic view showing a step subsequent to that of FIG. 31A.

### DETAILED DESCRIPTION OF THE PREFERRED EMBODIMENTS

Embodiments will be hereinafter described in detail with reference to the accompanying drawings. The accompanying drawings are schematic views, and are not strictly shown, and do not coincide with each other in reduced scale and the like. Also, the same reference sign is assigned to a constituent that corresponds to each constituent in the accompanying drawings, and a duplicated description of this constituent is omitted or simplified. A description of a constituent, which has not yet been omitted or simplified, is applied to a corresponding constituent a description of which has been omitted or simplified.

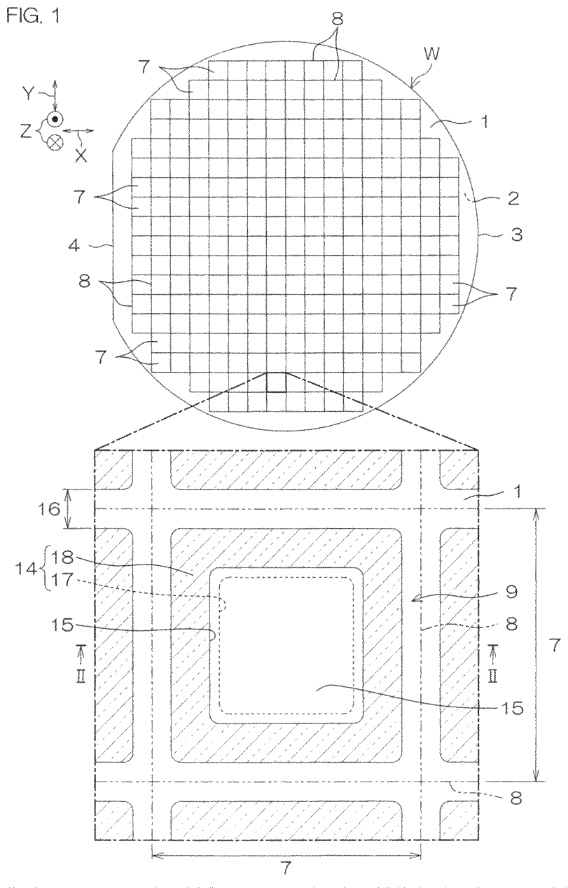

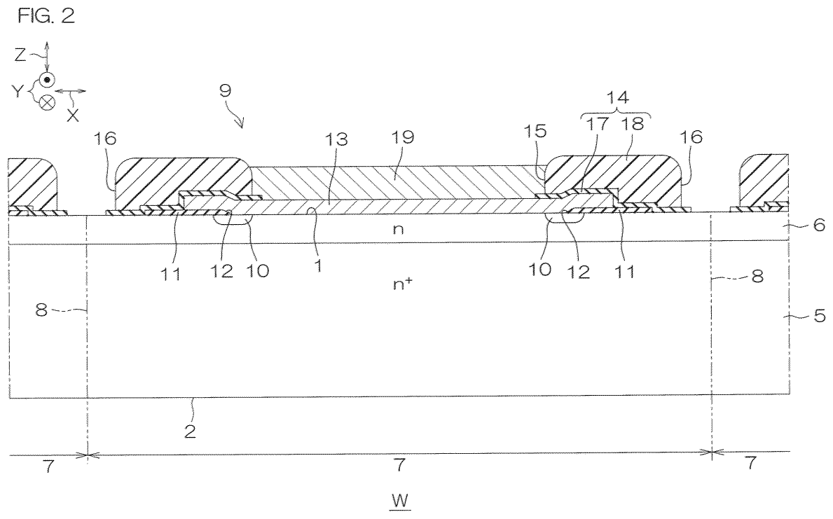

FIG. 1 is a plan view showing a configuration example of a wafer W that is to be used to manufacture a semiconductor device. FIG. 2 is a cross-sectional view along line II-II shown in FIG. 1. Referring to FIG. 1 and FIG. 2, the wafer W is formed in a disk shape in this embodiment. In this embodiment, the wafer W is made of a high-hard semiconductor wafer that has higher hardness than an Si (silicon) single crystal. Preferably, the wafer W is made of a wide bandgap semiconductor wafer including a wide bandgap semiconductor. The wide bandgap semiconductor is a semiconductor having a higher bandgap than the Si single crystal.

In this embodiment, the wafer W is made of an SiC wafer including a hexagonal SiC (silicon carbide) single crystal as an example of a wide bandgap semiconductor. The hexagonal SiC single crystal has a plurality of kinds of polytypes including 2H (Hexagonal)-SiC single crystal, 4H—SiC single crystal, 6H—SiC single crystal, etc. In this embodiment, an example in which the wafer W is made of a 4H—SiC single crystal is shown, and yet other polytypes are not excluded.

The wafer W has a first main surface 1 on one side, a second main surface 2 on the other side, and a side surface 3 that connects the first main surface 1 and the second main surface 2 together. One direction along the first main surface 1 is hereinafter referred to as a first direction X, and a direction perpendicular to the first direction X along the first main surface 1 is hereinafter referred to as a second direction Y, and a direction vertically intersecting the first main surface 1 is hereinafter referred to as a vertical direction Z. The first direction X may be an m-axial direction of the SiC single crystal, and the second direction Y may be an a-axial direction of the SiC single crystal. The first direction X may be an a-axial direction of the SiC single crystal, and the second direction Y may be an m-axial direction of the SiC single crystal.

The first main surface 1 and the second main surface 2 face a c-plane of the SiC single crystal. Preferably, the first main surface 1 faces a silicon surface of the SiC single crystal, and the second main surface 2 faces a carbon surface of the SiC single crystal. The first main surface 1 and the second main surface 2 may each have an off-angle that inclines in a predetermined off-direction at a predetermined angle with respect to the c-plane. In other words, a c-axis of the SiC single crystal may incline by an off-angle with respect to the vertical direction Z. Preferably, the off-direction is the a-axial direction ([11-20] direction) of the SiC single crystal. The off-angle may be more than 0° and not more than 10°. Preferably, the off-angle is 5° or less. Particularly preferably, the off-angle is not less than 2° and not more than 4.5°.

The wafer W has a mark 4 representing a crystal orientation of the SiC single crystal in the side surface 3. In this embodiment, the mark 4 includes an orientation flat that has been linearly cut out in a plan view seen from the vertical direction Z (hereinafter, referred to simply as a “plan view”). In this embodiment, the orientation flat extends in the second direction Y. The orientation flat is not necessarily required to extend in the second direction Y, and may extend in the first direction X. Of course, the mark 4 may include a first orientation flat extending in the first direction X and a first orientation flat extending in the second direction Y.

The wafer W may have a diameter of not less than 50 mm and not more than 300 mm (i.e., not less than 2 inches and not more than 12 inches) in a plan view. The diameter of the wafer W is defined by the length of a chord passing through the center of the wafer W outside the mark 4. The wafer W has a thickness of not less than 50 μm and not more than 1050 μm. Preferably, the wafer W is made of a thin wafer having a comparatively small thickness in a method for manufacturing a semiconductor device according to this embodiment. In this case, preferably, the thickness of the wafer W is not less than 50 μm and not more than 200 μm.

The wafer W includes an n-type (first conductivity type) first region 5 formed in a surface layer portion of the second main surface 2. The first region 5 is formed in a layer shape extending along the second main surface 2, and is exposed from the second main surface 2 and from the side surface 3. The first region 5 may have a thickness of not less than 45 μm and not more than 1000 μm. Preferably, the thickness of the first region 5 is 200 μm or less. In this embodiment, the first region 5 consists of a semiconductor substrate (in detail, SiC semiconductor substrate), and forms the second main surface 2 and a part of the side surface 3.

The wafer W includes an n-type second region 6 formed in a surface layer portion of the first main surface 1. The second region 6 has an n-type impurity concentration lower than the first region 5, and is electrically connected to the first region 5 inside the wafer W. The second region 6 is formed in a layer shape extending along the first main surface 1, and is exposed from the first main surface 1 and from the side surface 3. The second region 6 has a thickness less than the thickness of the first region 5 in the vertical direction Z.

The thickness of the second region 6 may be not less than 5 μm and not more than 50 μm. Preferably, the thickness of the second region 6 is not less than 10 μm and not more than 30 μm. In this embodiment, the second region 6 consists of an epitaxial layer (in detail, SiC epitaxial layer), and forms the first main surface 1 and a part of the side surface 3. In other words, the wafer W has a layered structure including an SiC semiconductor substrate and an SiC epitaxial layer.

The wafer W includes a plurality of device regions 7 and a plurality of scheduled-to-be-cut lines 8 that are provided at the first main surface 1. The plurality of device regions 7 are each set in a quadrangular shape in a plan view. In this embodiment, the plurality of device regions 7 are arranged in a matrix manner along the first direction X and along the second direction Y in a plan view. In other words, the first direction X is a first array direction of the plurality of device regions 7, and the second direction Y is a second array direction of the plurality of device regions 7.

The plurality of device regions 7 are each arranged at a distance inwardly from a peripheral edge portion of the first main surface 1 in a plan view. In other words, the wafer W has an inward portion having the plurality of device regions 7 and a peripheral edge portion not having the device region 7. The plurality of scheduled-to-be-cut lines 8 are set in a grid-shaped manner extending along the first direction X and along the second direction Y so as to divisionally form the plurality of device regions 7.

The wafer W further includes a plurality of functional devices 9 each of which is formed in each of the device regions 7 in the first main surface 1. Each of the functional devices 9 is formed by use of a part of the second region 6 at a distance inwardly from a peripheral edge of each of the device regions 7. Each of the functional devices 9 may include at least one among a switching device, a rectifying device, and a passive device.

The switching device may include at least one among MISFET (Metal Insulator Semiconductor Field Effect Transistor), BJT (Bipolar Junction Transistor), IGBT (Insulated Gate Bipolar Junction Transistor), and JFET (Junction Field Effect Transistor). The rectifying device may include at least one among a p-n junction diode, a pin junction diode, a Zener diode, SBD (Schottky Barrier Diode), and FRD (Fast Recovery Diode). The passive device may include at least one among a resistor, a capacitor, and a coil.

Each of the functional devices 9 may include a circuit network (e.g., integrated circuit such as LSI) in which at least two among the switching device, the rectifying device, and the passive device are combined together. In this embodiment, each of the functional devices 9 includes SBD. Structures of the plurality of device regions 7 (functional devices 9) are the same, and therefore the structure of the single device region 7 (functional device 9) will be hereinafter described.

The wafer W includes a p-type (second conductivity type) guard region 10 formed in the surface layer portion of the first main surface 1 in the device region 7. The guard region 10 is formed in a surface layer portion of the second region 6 at a distance inwardly from the peripheral edge of the device region 7. The guard region 10 is formed in an annular shape (in this embodiment, quadrangular annular shape) surrounding an inward portion of the device region 7 in a plan view. The guard region 10 has an inner edge portion on the inward portion side of the device region 7 and an outer edge portion of the peripheral side of the device region 7.

The wafer W includes a main surface insulating film 11 that covers the first main surface 1 in the device region 7. The main surface insulating film 11 may include a silicon oxide film. The main surface insulating film 11 has a contact opening 12 that exposes the inward portion of the device region 7 and an inner peripheral portion of the guard region 10. The main surface insulating film 11 covers the inward portion of the device region 7 at a distance inwardly from the peripheral edge of the device region 7, and exposes the first main surface 1 (second region 6) from a peripheral edge portion of the device region 7. In other words, the main surface insulating film 11 exposes a boundary portion of the plurality of device regions 7. Of course, the main surface insulating film 11 may cover the peripheral edge portion of the device region 7 (boundary portions of the plurality of device regions 7).

The wafer W includes a first main surface electrode 13 that covers the first main surface 1 in the device region 7. The first main surface electrode 13 is arranged at a distance inwardly from the peripheral edge of the device region 7. In this embodiment, the first main surface electrode 13 is formed in a quadrangular shape along the peripheral edge of the device region 7 in a plan view. The first main surface electrode 13 enters the contact opening 12 from above the main surface insulating film 11, and is electrically connected to the first main surface 1 and to the inner edge portion of the guard region 10. The first main surface electrode 13 makes a Schottky junction with the second region 6 (first main surface 1).

The first main surface electrode 13 may have a layered structure including a Ti-based metal film and an Al-based metal film. The Ti-based metal film may have a single layer structure consisting of a Ti film or a TiN film. The Ti-based metal film may have a layered structure including a Ti film and a TiN film that are stacked together in arbitrary order. Preferably, the Al-based metal film is thicker than the Ti-based metal film. The Al-based metal film may include at least one among a pure Al film (Al film whose purity is 99% or more), an AlCu alloy film, an AlSi alloy film, and an AlSiCu alloy film.

The wafer W includes an insulating film 14 that covers the first main surface electrode 13 in the device region 7. The insulating film 14 covers a peripheral edge portion of the first main surface electrode 13 at a distance inwardly from the peripheral edge of the device region 7. The insulating film 14 defines a pad opening 15 in the inward portion of the device region 7, and defines a street opening 16 in the peripheral edge portion of the device region 7. The pad opening 15 exposes an inward portion of the first main surface electrode 13. The street opening 16 extends along the peripheral edge of the device region 7, and exposes the first main surface 1.

In detail, the street opening 16 is divisionally formed in a grid shape extending in the first and second directions X and Y in the first direction X by the plurality of insulating films 14 adjoining in the first and second directions X and Y, and exposes boundary portions of the plurality of device regions 7 (plurality of scheduled-to-be-cut lines 8). If the main surface insulating film 11 covering the peripheral edge portion of the device region 7 is formed, the insulating film 14 defines the street opening 16 that exposes the main surface insulating film 11.

In this embodiment, the insulating film 14 has a layered structure including an inorganic insulating film 17 (inorganic film) and an organic insulating film 18 (organic film) that are stacked together in this order from the first main surface electrode 13 side. Preferably, the inorganic insulating film 17 includes an insulating material differing from that of the main surface insulating film 11. In this embodiment, the inorganic insulating film 17 is made of a silicon nitride film. The organic insulating film 18 is thicker than the inorganic insulating film 17, and forms a main body of the insulating film 14.

Preferably, the organic insulating film 18 is made of photosensitive resin. The organic insulating film 18 may include at least one among a polyimide film, a polyamide film, and a polybenzoxazole film. The organic insulating film 18 may cover the inorganic insulating film 17 so as to expose either one or both of an inner peripheral portion and an outer peripheral portion of the inorganic insulating film 17. In this embodiment, the organic insulating film 18 exposes both of the inner peripheral portion and the outer peripheral portion of the inorganic insulating film 17, and defines the inorganic insulating film 17, the pad opening 15, and the street opening 16.

The wafer W includes a pad electrode 19 that is arranged in the pad opening 15 and that covers the inward portion of the first main surface electrode 13 in the device region 7. The pad electrode 19 has an electrode surface placed in the pad opening 15, and is not arranged outside the pad opening 15. The pad electrode 19 may have a layered structure including an Ni film stacked on the first main surface electrode 13, a Pd film stacked on the Ni film, and an Au film stacked on the Pd film.

The presence or absence of both the insulating film 14 and the pad electrode 19 is optional. Therefore, a wafer W that has the insulating film 14 and that does not have the pad electrode 19 may be employed. Also, a wafer W that does not have the insulating film 14 and that has the pad electrode 19 may be employed. Also, a wafer W that does not have both of the insulating film 14 and the pad electrode 19 may be employed.

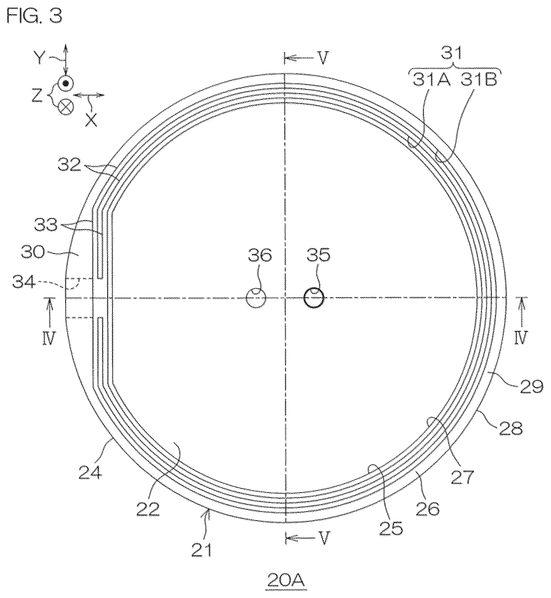

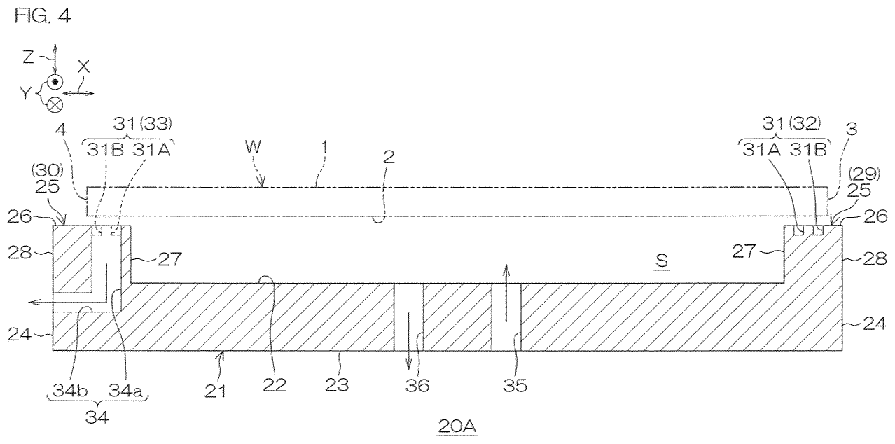

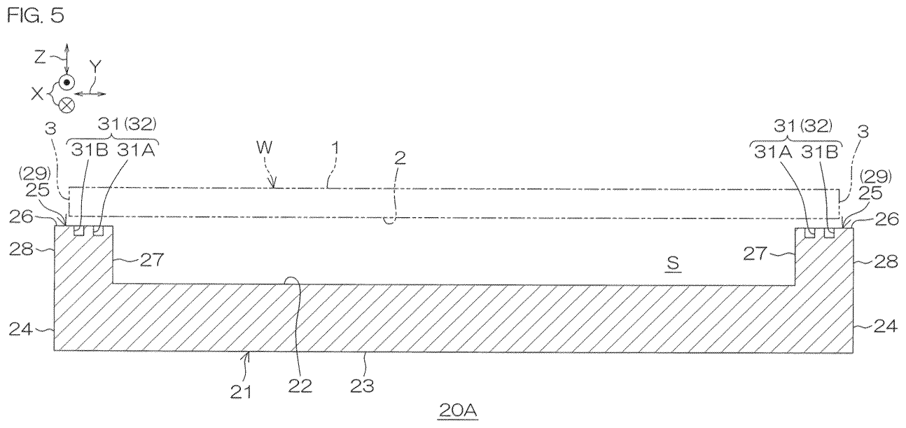

FIG. 3 is a plan view showing a support stage 20A according to the first embodiment. FIG. 4 is a cross-sectional view along line IV-IV shown in FIG. 3. FIG. 5 is a cross-sectional view along line V-V shown in FIG. 3. The support stage 20A is a jig used to support the wafer W that is to be supported. In FIG. 4 and FIG. 5, the wafer W is shown by an alternate long and two short dashed line.

Referring to FIG. 3 to FIG. 5, the support stage 20A includes a metallic base portion 21. The base portion 21 may be made of stainless steel (for example, SUS303, SUS304, or the like). In this embodiment, the base portion 21 is formed in a disk shape. The base portion 21 has a first plate surface 22 on one side, a second plate surface 23 on the other side, and a sidewall 24 that connects the first plate surface 22 and the second plate surface 23 together. Preferably, the base portion 21 has a diameter exceeding the diameter of the wafer W. The diameter of the base portion 21 is defined by the length of a chord passing through the center of the first plate surface 22 (second plate surface 23). Preferably, the diameter of the base portion 21 is larger by a value of not less than 1 mm and not more than 20 mm than the diameter of the wafer W from the viewpoint of the positioning accuracy of the wafer W.

The support stage 20A includes a metallic support portion 25 erected at a peripheral edge portion of the first plate surface 22 in the base portion 21. The support portion 25 may be made of stainless steel (for example, SUS303, SUS304, or the like). In this embodiment, the support portion 25 is formed integrally with the base portion 21. The support portion 25 is configured to support the wafer W in a state in which the second main surface 2 of the wafer W is brought into contact with the support portion 25 and is at a distance from the first plate surface 22 (base portion 21). Hereinafter, the term “contact of the second main surface 2 with the support portion 25” includes a case in which the second main surface 2 of the wafer W is to be come into direct contact with the support portion 25, and, in addition, a case in which the second main surface 2 of the wafer W is to be come into indirect contact with the support portion 25 with another member, such as a cushioning material (e.g., resin etc.), between the second main surface 2 and the support portion 25.

In this embodiment, the support portion 25 is erected in a belt shape extending along a peripheral edge of the first plate surface 22. In detail, the support portion 25 is erected in an annular shape (in this embodiment, circular annular shape) surrounding an inward portion of the first plate surface 22 in a plan view, and defines the first plate surface 22 and a circular recess. The support portion 25 is brought into contact with a peripheral edge portion of the second main surface 2 of the wafer W over the entire periphery. In detail, preferably, the support portion 25 is configured to coincide with a peripheral edge portion, which does not have the device region 7, of the wafer W in a state in which the wafer W is in contact with the support portion 25 in a plan view. In this case, particularly preferably, the support portion 25 is configured not to coincide with the plurality of device regions 7 in a plan view.

The support portion 25 has a contact surface 26 with which the second main surface 2 is to be come into contact, an inner wall 27 on the inward side of the support stage 20A, and an outer wall 28 on the peripheral side of the support stage 20A. Preferably, the contact surface 26 is a flat surface extending in parallel with the second main surface 2. The inner wall 27 is continuous with the first plate surface 22 of the support stage 20A, and defines the recess with the first plate surface 22. The outer wall 28 is continuous with the sidewall 24 of the support stage 20A. Of course, the outer wall 28 may be placed on the inward side of the first plate surface 22 with respect to the sidewall 24.

In this embodiment, the support portion 25 has a circular arc contact portion 29 and a linear contact portion 30. The circular arc contact portion 29 is a portion that has a side that extends in a circular-arc shape along a circular-arc part, which excludes the mark 4 (orientation flat), of the wafer W and that is to be come into contact with this circular-arc part. The linear contact portion 30 is a portion that has a side extending linearly along the mark 4 and that is to be come into contact with the mark 4 of the wafer W. The linear contact portion 30 is formed wider than the circular arc contact portion 29.

Preferably, the width of the support portion 25 falls within a range of not less than 1 mm and not more than 20 mm. The width of the support portion 25 is a width in a direction perpendicular to a direction in which the support portion 25 extends. Preferably, the thickness of the support portion 25 is not less than 1 mm and not more than 10 mm. Preferably, the ratio of the thickness to the width of the support portion 25 is 1 or less. The thickness of the support portion 25 is the thickness in the vertical direction Z of the support portion 25. The support portion 25 may be formed by hollowing a part of the first plate surface 22 of the base portion 21 toward the second plate surface 23 by cutting machining, press working, or the like. Of course, the support portion 25 may be structurally independent of the base portion 21, and may be attached to the support stage 20A by welding (heat sealing), crimping (pressure bonding), fitting, screwing, or the like.

The support stage 20A includes at least one suction groove 31 provided at the support portion 25. The suction groove 31 is a groove to which a suction force from the support portion 25 side toward the base portion 21 side is to be given from the outside, and is provided at the contact surface 26. The suction groove 31 is configured so that a suction force (adsorption force) is given to the second main surface 2 in a state in which the second main surface 2 is in contact with the contact surface 26.

The suction groove 31 is optional in number. In this embodiment, the support stage 20A includes a plurality of suction grooves 31. In this embodiment, the plurality of suction grooves 31 include a first suction groove 31A on the inner wall 27 side of the support portion 25 and a second suction groove 31B on the outer wall 28 side of the support portion 25. The first suction groove 31A is formed in a belt shape extending along the inner wall 27 in a plan view. In this embodiment, the first suction groove 31A is formed in an annular shape (in this embodiment, circular annular shape) surrounding the inner wall 27 in a plan view. Of course, the first suction groove 31A may be formed in an ended belt shape extending along the inner wall 27 in a plan view.

The second suction groove 31B is formed in the contact surface 26 at a distance from the first suction groove 31A to the outer wall 28 side in a region between the first suction groove 31A and the outer wall 28. The second suction groove 31B is formed in a belt shape extending along the first suction groove 31A in a plan view. In this embodiment, the second suction groove 31B is formed in an annular shape (in this embodiment, circular annular shape) surrounding the first suction groove 31A in a plan view. Of course, the second suction groove 31B may be formed in an ended belt shape extending along the first suction groove 31A in a plan view.

The first suction groove 31A and the second suction groove 31B each include a circular arc portion 32 and a linear portion 33. The circular arc portion 32 is a portion that extends in a circular-arc shape along the circular arc contact portion 29 of the support portion 25. The linear portion 33 is a portion that extends linearly along the linear contact portion 30 of the support portion 25. Preferably, the first suction groove 31A and the second suction groove 31B each include the circular arc portion 32 and the linear portion 33 even when these grooves are each formed in an ended belt shape.

Preferably, the width of each suction groove 31 falls within a range of not less than 1 mm and not more than 5 mm. The width of each suction groove 31 is a width in a direction perpendicular to a direction in which each suction groove 31 extends. Preferably, the depth of each suction groove 31 is equal to or less than the depth of the support portion 25. Preferably, the depth of each suction groove 31 is less than the depth of the support portion 25. The depth of each suction groove 31 may be not less than 1 mm and not more than 10 mm.

The support stage 20A includes a suction hole 34 provided in the inside of either one or both of the base portion 21 and the support portion 25 (in this embodiment, both) so as to communicate with each suction groove 31. The suction hole 34 defines a suction flow path by which a suction force from the outside to the suction groove 31 is to be given. In this embodiment, the suction hole 34 is provided on the linear contact portion 30 side of the support portion 25.

In detail, the suction hole 34 includes a first hole 34a on the support portion 25 side and a second hole 34b on the base portion 21 side. The first hole 34a is dug down from the contact surface 26 toward the second plate surface 23 side so as to communicate with each suction groove 31 (linear portion 33). The first hole 34a may be formed in a circular shape or in a quadrangular shape in a plan view. The second hole 34b is provided at a part positioned under the support portion 25 in the base portion 21.

The second hole 34b extends in a lateral direction (in this embodiment, first direction X) along the first plate surface 22 from the sidewall 24 of the base portion 21, and communicates with the first hole 34a. The second hole 34b may be formed in a circular shape or in a quadrangular shape when viewed from a normal direction of the sidewall 24. Of course, the suction hole 34 is provided on the circular arc contact portion 29 side of the support portion 25. Also, the first hole 34a and the second hole 34b may be formed so as to pass through the base portion 21 and the support portion 25 in the vertical direction Z.

The support stage 20A includes at least one (in this embodiment, one) ejecting hole 35 provided in an inward portion of the base portion 21 (See the thick line portion in the accompanying drawings. The same applies hereinafter) The ejecting hole 35 may be referred to as a “discharge hole.” The ejecting hole 35 is configured so that a gas is to be supplied from the outside into the ejecting hole 35 and so that the gas is to be ejected toward the second main surface 2 of the wafer W from the ejecting hole 35. In detail, the ejecting hole 35 is configured so that a gas having a flow rate (pressure) that corrects a warpage of the wafer W is to be supplied from the outside and so that the gas is to be ejected toward the second main surface 2 in a state in which this gas holds this pressure. The gas may be air.

The ejecting hole 35 is provided in a region surrounded by the support portion 25 at a distance from the support portion 25. The ejecting hole 35 passes through the first plate surface 22 and the second plate surface 23 in the vertical direction Z. Preferably, the ejecting hole 35 is provided in a central portion of the first plate surface 22. Preferably, the ejecting hole 35 is provided at a position that deviates from the center of the base portion 21. Preferably, the ejecting hole 35 is provided at a position at which a distance from the center of the base portion 21 becomes less than a distance from the support portion 25.

The ejecting hole 35 may be provided so as to deviate from the center of the first plate surface 22 in either the first direction X or the second direction Y or in both the first direction X and the second direction Y. In this embodiment, the ejecting hole 35 is provided at a distance from the center of the first plate surface 22 on one side in the first direction X (i.e., side opposite to the linear contact portion 30). In other words, the ejecting hole 35 is arranged at a distance from the center of the first plate surface 22 in a direction perpendicular to an extending direction of the linear contact portion 30 (orientation flat of the wafer W).

In this embodiment, the ejecting hole 35 is formed in a circular shape in a plan view. The planar shape of the ejecting hole 35 is optional. The ejecting hole 35 may be formed in a quadrangular shape, a hexagonal shape, an elliptical shape, or the like in a plan view. Preferably, the width (maximum value) of the ejecting hole 35 exceeds the width of each suction groove 31. Particularly preferably, the width of the ejecting hole 35 exceeds a total value of the widths of the plurality of suction grooves 31. The width of the ejecting hole 35 may be not less than 1 mm and not more than 20 mm. In this embodiment, the width of the ejecting hole 35 is defined by the length of a chord passing through the center of the ejecting hole 35.

The support stage 20A includes at least one (in this embodiment, one) exhaust hole 36 that is provided in either one or both of the base portion 21 and the support portion 25 (in this embodiment, in the base portion 21) (see the thin line portion of FIG. 3). The exhaust hole 36 is configured to discharge a gas ejected from the ejecting hole 35 from a space S between the base portion 21, the support portion 25, and the wafer W (second main surface 2). In other words, the exhaust hole 36 is configured so that a rise of atmospheric pressure of the space S caused by the ejected gas is to be restrained.

The exhaust hole 36 is provided in a region surrounded by the support portion 25 at a distance from the support portion 25 and from the ejecting hole 35. The exhaust hole 36 passes through the first plate surface 22 and the second plate surface 23 in the vertical direction Z. Preferably, the exhaust hole 36 is provided so as to adjoin the ejecting hole 35 in the central portion of the first plate surface 22. Preferably, the exhaust hole 36 is provided at a position that deviates from the center of the base portion 21. Preferably, the exhaust hole 36 is provided at a position at which the distance from the center of the base portion 21 becomes less than the distance from the support portion 25.

The exhaust hole 36 may be provided so as to deviate from the center of the first plate surface 22 in either the first direction X or the second direction Y or in both the first direction X and the second direction Y. In this embodiment, the exhaust hole 36 is provided at a distance from the center of the first plate surface 22 on the other side (linear contact portion 30 side) in the first direction X. In other words, the exhaust hole 36 is arranged at a distance from the center of the first plate surface 22 in a direction perpendicular to an extending direction of the linear contact portion 30 (orientation flat of the wafer W). Also, the exhaust hole 36 faces the ejecting hole 35 across the center of the first plate surface 22 in a plan view. In other words, when a line is defined as being perpendicular to the linear contact portion 30, the exhaust hole 36 is placed on the line together with the ejecting hole 35. Preferably, the exhaust hole 36 is placed on a concentric circle surrounding the center of the first plate surface 22 together with the ejecting hole 35.

In this embodiment, the exhaust hole 36 is formed in a circular shape in a plan view. The planar shape of the exhaust hole 36 is optional. The exhaust hole 36 may be formed in a quadrangular shape, a hexagonal shape, an elliptical shape, or the like in a plan view. Preferably, the width (maximum value) of the exhaust hole 36 exceeds the width of each suction groove 31. Particularly preferably, the width of the exhaust hole 36 exceeds a total value of the widths of the plurality of suction grooves 31. The width of the exhaust hole 36 may be not less than 1 mm and not more than 20 mm. In this embodiment, the width of the exhaust hole 36 is defined by the length of a chord passing through the center of the exhaust hole 36. The width of the exhaust hole 36 may be equal to or more than the width of the ejecting hole 35, or may be less than the width of the ejecting hole 35. In this embodiment, the width of the exhaust hole 36 is substantially equal to the width of the ejecting hole 35.

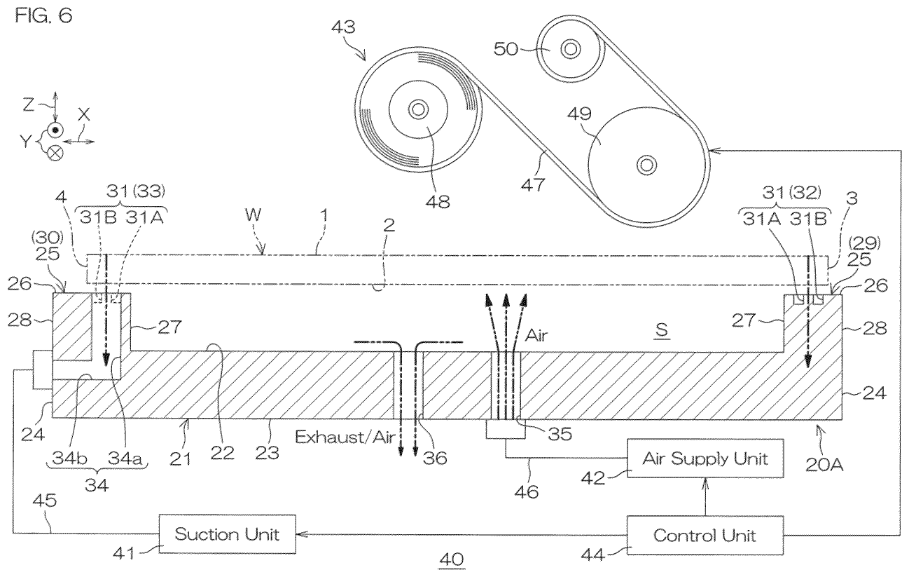

FIG. 6 is a schematic view showing a configuration example of a support device 40 to which the support stage 20A shown in FIG. 3 has been applied. In FIG. 6, the wafer W is shown by an alternate long and two short dashed line. Referring to FIG. 6, the support device 40 is a processing apparatus that adsorbs and supports the wafer W from the second main surface 2 side with the support stage 20A and that applies a predetermined process to the first main surface 1 of the wafer W. The support device 40 includes the support stage 20A, a suction unit 41, a gas supply unit 42, a processing unit 43, and a control unit 44.

The suction unit 41 includes, for example, a suction pump (e.g., vacuum pump), and is connected to the suction hole 34 through a first pipe 45. The gas supply unit 42 includes, for example, a gas supply pump (e.g., air compressor), and is connected to the ejecting hole 35 through a second pipe 46. A gas ejected from the ejecting hole 35 is to be come into contact with the second main surface 2 of the wafer W, and is discharged outwardly through the exhaust hole 36. In other words, the gas supply unit 42 is not a pressurizing unit that pressurizes a space S defined by the base portion 21, the support portion 25, and the wafer W.

The processing unit 43 is configured to apply a predetermined process to the first main surface 1 of the wafer W. In this embodiment, the processing unit 43 consists of a tape transfer unit that removes a foreign substance adhered to the first main surface 1 side with an adhesive tape 47. As an example, the processing unit 43 may include the adhesive tape 47, a first roller 48 that winds the tape 47, a second roller 49 that allows the tape 47 to adhere to the first main surface 1 of the wafer W, and a third roller 50 that winds up the tape 47 to which the foreign substance adhered.

The control unit 44 is connected to the suction unit 41, to the gas supply unit 42, and to the processing unit 43, and controls the suction unit 41, the gas supply unit 42, and the processing unit 43. The control unit 44 includes a CPU and a memory (for example, ROM, RAM, a nonvolatile memory, or the like), and controls the suction unit 41, the gas supply unit 42, and the processing unit 43 on the basis of a predetermined process recipe stored in the memory with a predetermined processing operation.

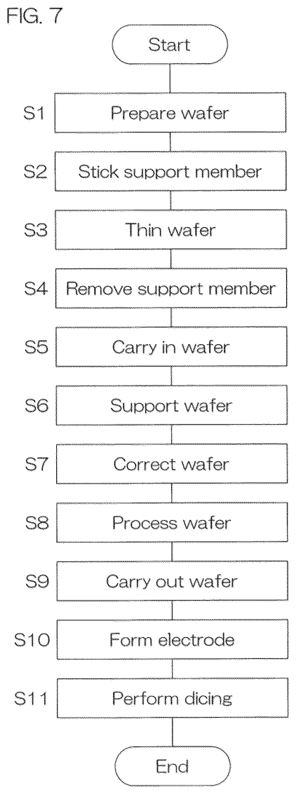

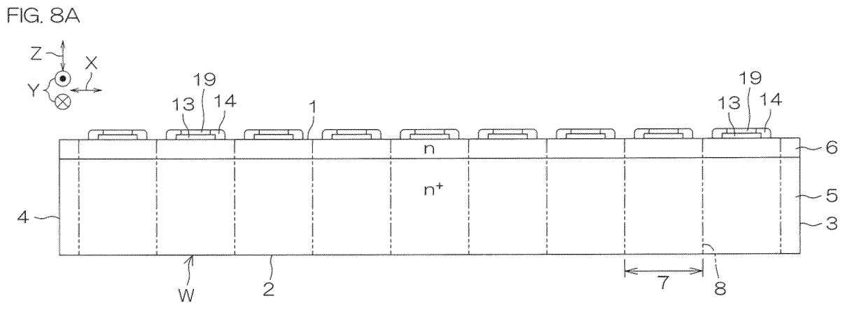

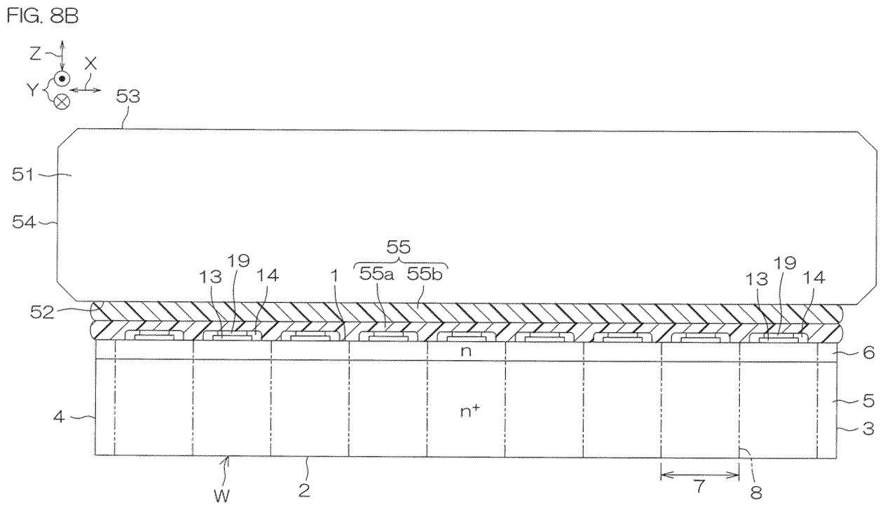

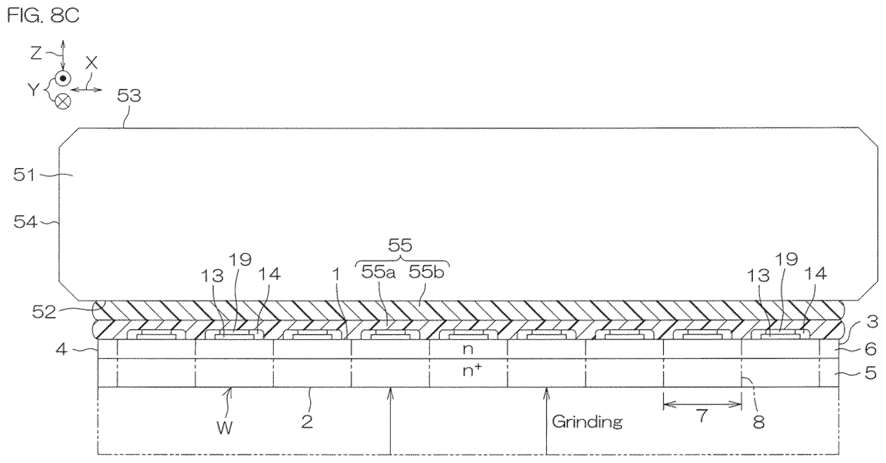

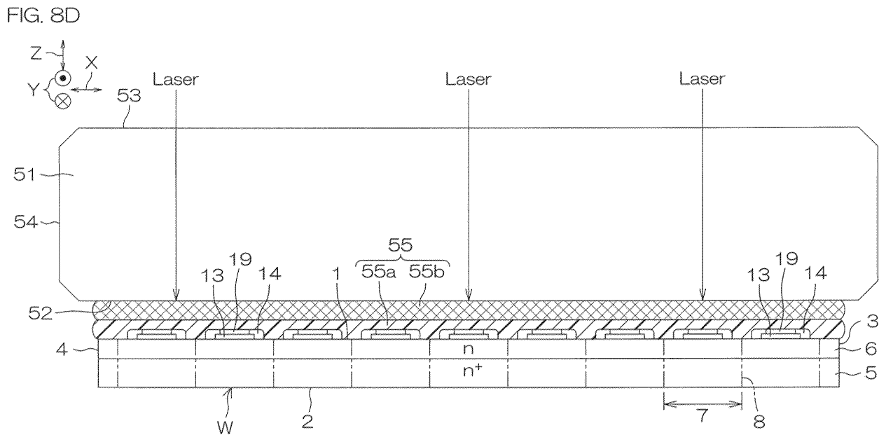

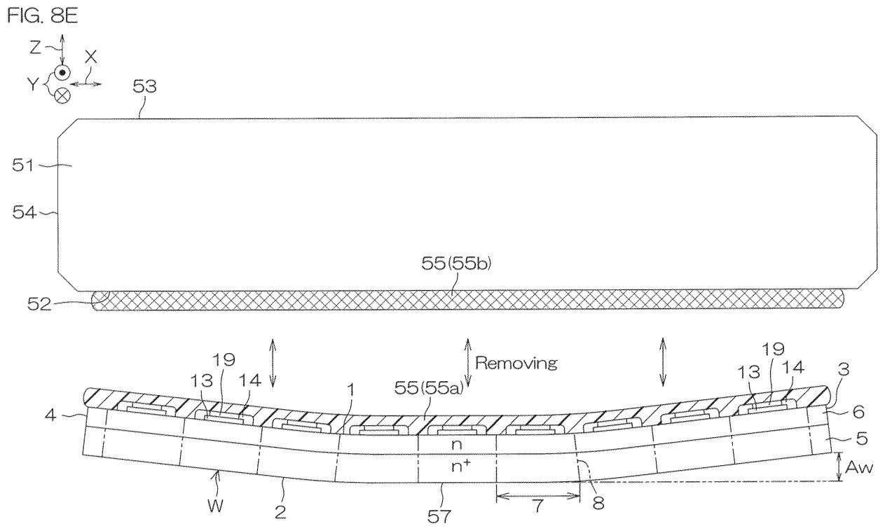

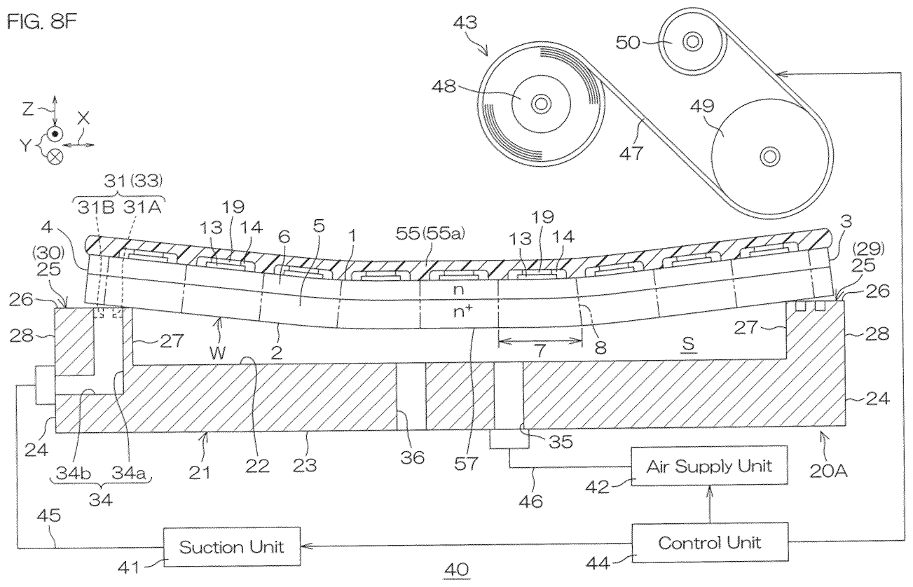

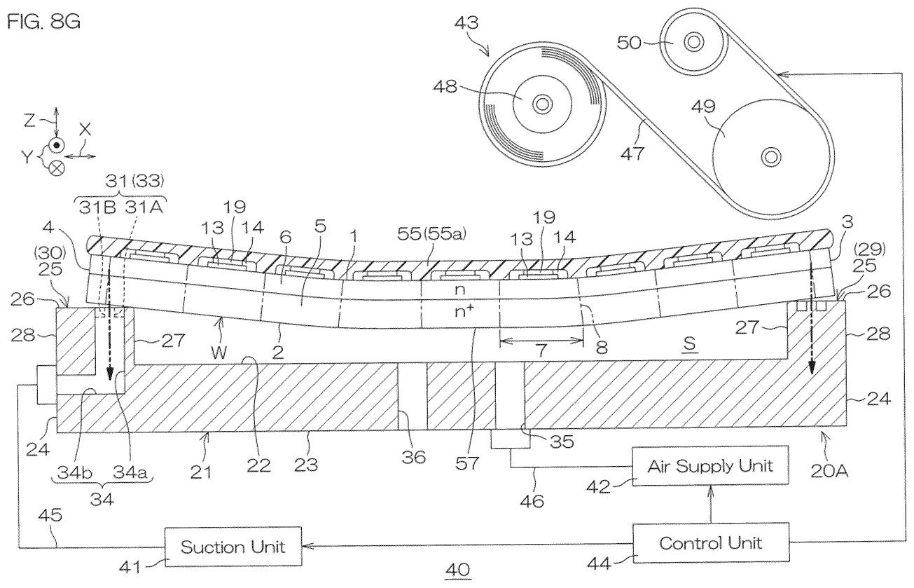

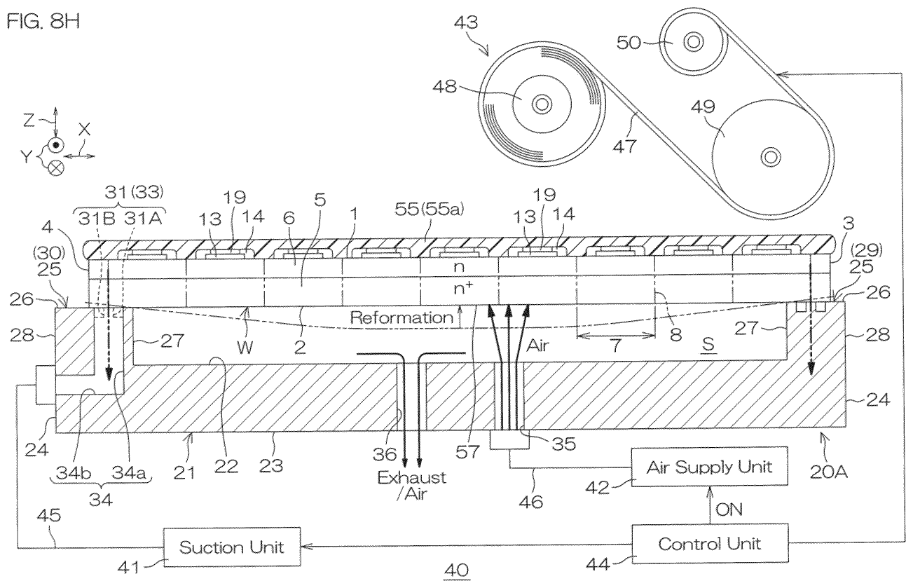

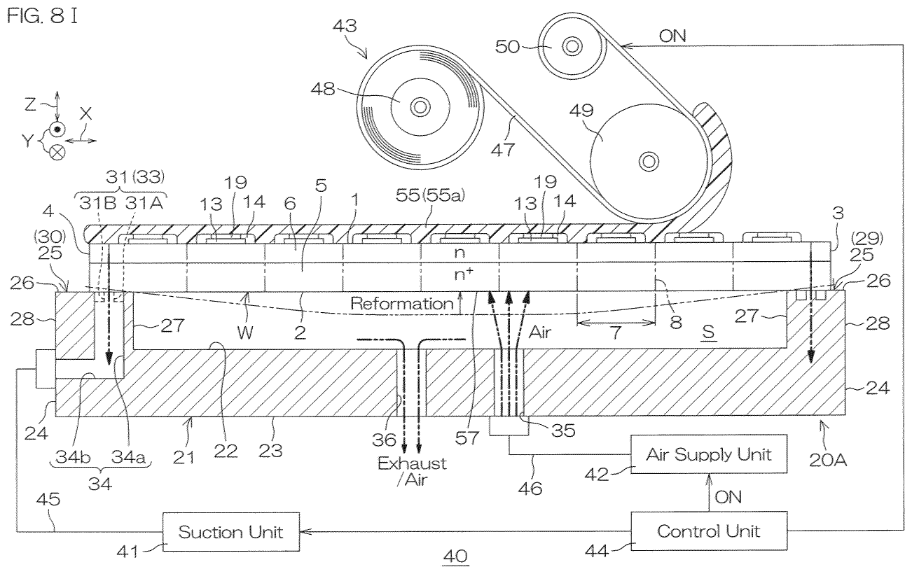

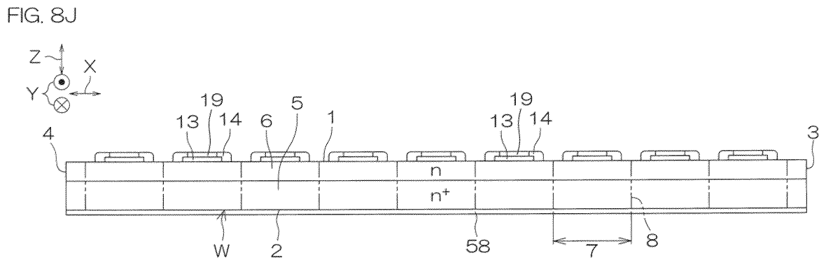

FIG. 7 is a flowchart showing an example of a method for manufacturing a semiconductor device. FIG. 8A to FIG. 8J are schematic views each of which shows a step of the method for manufacturing the semiconductor device. In FIG. 8A to FIG. 8J, the plurality of device regions 7 and the plurality of scheduled-to-be-cut lines 8 are each shown by the alternate long and two short dashed line.

Referring to FIG. 8A, first, a preparation step of the wafer W is performed (Step S1 of FIG. 7). Thereafter, referring to FIG. 8B, a wafer support plate 51 is prepared separately, and a step of supporting the wafer W is performed by the wafer support plate 51 (Step S2 of FIG. 7). A material for the wafer support plate 51 is optional as far as the wafer W can be supported from the first main surface 1 side. The wafer support plate 51 may be made of the same material as the wafer W, or may be made of a material differing from that of the wafer W.

The wafer support plate 51 may be made of an inorganic substance plate, an organic substance plate, a metallic plate, a crystal plate, or an amorphous plate, each of which is machined in a disk shape. Preferably, the wafer support plate 51 is made of a light transmissive material or a transparent material. In this embodiment, the wafer support plate 51 is made of an amorphous plate (in detail, glass plate (silicon oxide plate)). Preferably, the wafer support plate 51 is an impurity-free plate if the wafer support plate 51 is made of a crystal plate or an amorphous plate.

The wafer support plate 51 has the supporting side surface 54 connecting together the first support plate surface 52 on one side (the wafer W side), the second support plate surface 53 on the other side, the first support plate surface 52, and the second support plate surface 53. The diameter and the thickness of the wafer support plate 51 are optional. However, from the viewpoint of handling, it is preferable for the wafer support plate 51 to have a diameter equal to or more than the wafer W. Also, preferably, the wafer support plate 51 has a thickness equal to or more than the wafer W. In this embodiment, the wafer support plate 51 has a diameter and a thickness exceeding the diameter and the thickness of the wafer W. A corner portion of the wafer support plate 51 may be chamfered.

The first support plate surface 52 of the wafer support plate 51 is stuck onto the first main surface 1 of the wafer W through an adhesive layer 55 including an adhesive agent and a release agent. The adhesive layer 55 may be a multilayer film formed by separating the adhesive agent and the release agent from each other, or may be a monolayer film in which the release agent is included in the adhesive agent. In this embodiment, the adhesive layer 55 includes an adhesive agent film 55a and a release agent film 55b stacked together in this order from the first main surface 1 side. The adhesive agent film 55a may be formed by applying a liquid adhesive agent onto the first main surface 1, or may be formed by sticking a filmy adhesive agent onto the first main surface 1. The release agent film 55b may be formed by applying a liquid release agent onto the adhesive agent film 55a, or may be formed by sticking a filmy release agent onto the adhesive agent film 55a.

The adhesive agent film 55a and the release agent film 55b may be formed by sticking a single layer film or a laminating film including an adhesive agent and a release agent onto the first main surface 1. The adhesive agent (adhesive agent film 55a) may include at least one among UV curable resin, thermosetting resin, and a thermoplastic resin film. The release agent (release agent film 55b) is made of a resin having physical properties differing from physical properties of the adhesive agent (adhesive agent film 55a). The release agent (release agent film 55b) may include at least one of thermosetting resin and a thermoplastic resin film.

Thereafter, referring to FIG. 8C, a thinning step of the wafer W is performed (Step S3 of FIG. 7). In this step, the second main surface 2 is ground in a state in which the wafer W is supported by the wafer support plate 51. The grinding step of the second main surface 2 may be performed by a CMP (Chemical Mechanical Polishing) method. Thereby, the wafer W is thinned until the wafer W reaches a desired thickness.

In this embodiment, the wafer W is thinned until the wafer W reaches a thickness less than 150 μm. Preferably, the wafer W has a thickness of not less than 5 μm and not more than 100 μm after having been thinned. In this case, after having been thinned, the wafer W may have a layered structure including the first region 5 (semiconductor substrate) and the second region 6 (epitaxial layer), or may have a single layer structure consisting of the second region 6 (epitaxial layer). In other words, a semiconductor device having a layered structure including the first region 5 and the second region 6 may be manufactured, or a semiconductor device having a single layer structure consisting of the second region 6 may be manufactured.

Thereafter, referring to FIG. 8D, a removing step of the wafer support plate 51 is performed (Step S4 of FIG. 7). In this step, a laser beam (for example, YAG laser) is irradiated to the adhesive layer 55 by a laser irradiation method, and a release agent included in the adhesive layer 55 is carbonized. In this embodiment, a laser beam is irradiated to the release agent film 55b, and the release agent film 55b is carbonized. Preferably, the laser beam is irradiated from the second support plate surface 53 side of the wafer support plate 51 toward the release agent film 55b through the wafer support plate 51. According to this step, the laser beam is irradiated toward the release agent film 55b from the wafer support plate 51 side on which the number of shielding objects is small, and therefore the release agent film 55b is appropriately carbonized. Also, the laser beam is irradiated toward the release agent film 55b without the wafer W, and therefore damage on the wafer W, which is caused by the laser beam, is restrained.

Thereafter, referring to FIG. 8E, the wafer support plate 51 is peeled off from the wafer W. After the wafer support plate 51 has been peeled off, a part of the adhesive layer 55 remains in a state of having adhered onto the first main surface 1 of the wafer W. In this embodiment, the adhesive agent film 55a of the adhesive layer 55 remains in a state in which the adhesive agent film 55a has adhered onto the first main surface 1 of the wafer W. In this embodiment, the wafer W, which has been thinned and which has been released from the wafer support plate 51, has the warpage having the center of curvature on the first main surface 1. In other words, the wafer W has a concavely curved warpage in which the height position of a central portion of the wafer W is placed relatively downwardly with respect to the height position of a peripheral edge portion of the wafer W. The warpage of the wafer W occurs resulting from the stress of a structural component (for example, the first main surface electrode 13 or the like) on the first main surface 1 side.

In detail, the wafer W has the warpage starting-point portion 57 extending along a first crystal axis of an SiC single crystal with respect to the direction along the first main surface 1 at a central portion of the wafer W. In this embodiment, the warpage starting-point portion 57 is in a valley-fold state. The warpage of the wafer W is formed so as to reach a valley-fold state in which the first main surface 1 (silicon surface) and the second main surface 2 (carbon surface) are inclined upwardly in proportion to retreat from the warpage starting-point portion 57 toward the second crystal axis side of the SiC single crystal perpendicular to the first crystal axis of the SiC single crystal. The first crystal axis may be an m-axial direction of the SiC single crystal, and the second crystal axis may be an a-axial direction of the SiC single crystal. The first crystal axis may be an a-axial direction of the SiC single crystal, and the second crystal axis may be an m-axial direction of the SiC single crystal.

Two points placed on the warpage starting-point portion 57 in the peripheral edge of the wafer W are placed on the same plane. Because of the warpage, two points placed on the second crystal axis perpendicular to the warpage starting-point portion 57 in the peripheral edge of the wafer W are placed on a plane (on a plane placed relatively upwardly with respect to the warpage starting-point portion 57) different from the plane on which the two points placed on the warpage starting-point portion 57 are placed.

The magnitude of the warpage generated on one side of the second crystal axis with respect to the warpage starting-point portion 57 and the magnitude of the warpage generated on the other side of the second crystal axis with respect to the warpage starting-point portion 57 do not necessarily coincide with each other. Therefore, two points placed on the single second crystal axis in the peripheral edge of the wafer W may be placed on the same plane, or may be placed on mutually different planes. The wafer W may have an amount of warpage Aw of not less than 100 μm and not more than 10000 μm. The amount of warpage Aw of the wafer W is defined by a maximum distance along the vertical direction Z of a gap formed between a plane on which the wafer W is arranged and the second main surface 2.

Referring to FIG. 8F, the wafer W having a foreign substance (in this embodiment, adhesive agent film 55a) adhered onto the first main surface 1 is carried into the support device 40 after the step of thinning the wafer W is completed (Step S5 of FIG. 7). The wafer W is placed on the support stage 20A in a state in which the second main surface 2 is in contact with the support portion 25 of the support stage 20A (Step S6 of FIG. 7). Thereafter, referring to FIG. 8G, the suction unit 41 is controlled in an ON state, and a suction force is given to the suction groove 31. Thereby, a suction force toward the support stage 20A side is given from the suction groove 31 to the peripheral edge portion of the second main surface 2, and the wafer W is adsorbed and supported by the support portion 25.

The central portion of the wafer W may be placed on the first plate surface 22 side of the base portion 21 with respect to the contact surface 26 of the support portion 25, and the peripheral edge portion of the wafer W may be placed on the contact surface 26 of the support portion 25. Preferably, the wafer W is away from the first plate surface 22. The peripheral edge portion of the wafer W has stress urged in a direction opposite to a sucking direction (i.e., direction away from the support portion 25) due to the warpage. Therefore, the adsorption of the second main surface 2 with respect to the contact surface 26 is in an insufficient state. A case in which a gap caused by the warpage is formed between the second main surface 2 and the contact surface 26 is exemplified as an aspect that occurs when the adsorption is insufficient.

Thereafter, referring to FIG. 8H, a step of correcting the warpage of the wafer W is performed (Step S7 of FIG. 7). In this step, the gas supply unit 42 is controlled in an ON state in a state in which the exhaust hole 36 is opened, and a gas having a flow rate (pressure) to correct the warpage of the wafer W is supplied to the ejecting hole 35. The ejecting hole 35 ejects the gas having the flow rate (pressure) to correct the warpage toward the second main surface 2. In this embodiment, the ejected gas is brought into contact with the central portion of the second main surface 2. In detail, the ejected gas is brought into contact with the warpage starting-point portion 57 of the wafer W or with surroundings of the warpage starting-point portion 57.

Thereby, a pressing force (correcting force) in a direction away from the base portion 21 (first plate surface 22) is given to the central portion of the second main surface 2. In other words, in this step, a suction force in a direction toward the base portion 21 is given to the peripheral edge portion of the second main surface 2, and a pressing force in the direction away from the base portion 21 is given to the central portion of the second main surface 2. The wafer W is to be dropped off from the support portion 25 when the pressing force exceeds the suction force. Therefore, the pressing force is adjusted so as to fall within a range equal to or less than the suction force (preferably, a range less than the suction force).

Through this step, the central portion of the wafer W is displaced in a direction away from the base portion 21, and the warpage of the wafer W is corrected. Thereby, a gap between the second main surface 2 and the contact surface 26 is reduced, and, as a result, the adsorption force of the second main surface 2 with respect to the contact surface 26 increases. The ejected gas comes into contact with the wafer W, and is then discharged outwardly from a space S defined by the base portion 21, the support portion 25 and the wafer W through the exhaust hole 36. Thereby, a rise in atmospheric pressure of the inside of the space S is restrained during the warpage correcting step is being performed.

Thereafter, referring to FIG. 8I, a predetermined processing step is applied to the first main surface 1 of the wafer W (Step S8 of FIG. 7). The processing step on the first main surface 1 side is performed in parallel with the warpage correcting step. In this embodiment, the processing step includes a removal step of removing the foreign substance on the first main surface 1 by the processing unit 43 (in this embodiment, a peel-off step of the adhesive agent film 55a). The processing unit 43 supplies the adhesive tape 47 onto the first main surface 1 so as to be stuck onto the adhesive agent film 55a, and peels off the adhesive agent film 55a from the first main surface 1 by winding up the tape 47 onto which the adhesive agent film 55a is stuck.

In this step, a tensile force of the tape 47 with respect to the first main surface 1 is added to the pressing force of the gas with respect to the second main surface 2. Therefore, this step is performed within a range in which an additional value of both the pressing force of the ejected gas and the tensile force of the tape 47 does not exceed the suction force on the support portion 25 side. In other words, an adjustment is performed so as to fall within a range in which the additional value of both the pressing force of the ejected gas and the tensile force of the tape 47 becomes equal to or less than the suction force (preferably, less than the suction force). Preferably, when a pressing force is given from the processing unit 43 to the wafer W, this pressing force is adjusted so as to be equal to or less than the tensile force of the tape 47. In the processing step of the first main surface 1, the warpage of the wafer W has been corrected, and therefore it is possible to apply appropriate processing to the first main surface 1. In other words, it is possible to appropriately remove the adhesive agent film 55a from the first main surface 1 by reducing the warpage.

Referring to FIG. 8J, after the processing step of the first main surface 1 is completed, the wafer W is carried out from the support device 40 (Step S9 of FIG. 7), and a second main surface electrode 58 is formed on the second main surface 2 (Step S10 of FIG. 7). The wafer W in which the second main surface electrode 58 has been formed may have a valley-fold-shaped or mountain-fold-shaped warpage caused by the stress of the second main surface electrode 58. Thereafter, the wafer W is cut along the scheduled-to-be-cut line 8, and a plurality of wide bandgap semiconductor devices (in this embodiment, SiC semiconductor devices) are cut out (Step S11 of FIG. 7). The semiconductor device is manufactured through a process including the aforementioned steps.

The formation step of the second main surface electrode 58 (Step S10 of FIG. 7) is enabled to be performed at an arbitrary timing after the thinning step of the wafer W (Step S3 of FIG. 7) is completed. For example, the formation step of the second main surface electrode 58 (Step S10 of FIG. 7) may be performed after the thinning step of the wafer W (Step S3 of FIG. 7) is completed and before the removal step of the wafer support plate 51 (Step S4 of FIG. 7) is completed.

In this case, each step from the removal step of the wafer support plate 51 (Step S4 of FIG. 7) to the carry-out step of the wafer W (Step S9 of FIG. 7) is performed in a state in which the second main surface electrode 58 has been formed on the second main surface 2. Therefore, the wafer W is placed on the support stage 20A in a state in which the second main surface electrode 58 is in contact with the support portion 25 of the support stage 20A (Step S6 of FIG. 7). A case in which the second main surface 2 of the wafer W is brought into contact with the support portion 25 through the second main surface electrode 58 is also included in “contact of the second main surface 2 with the support portion 25.”

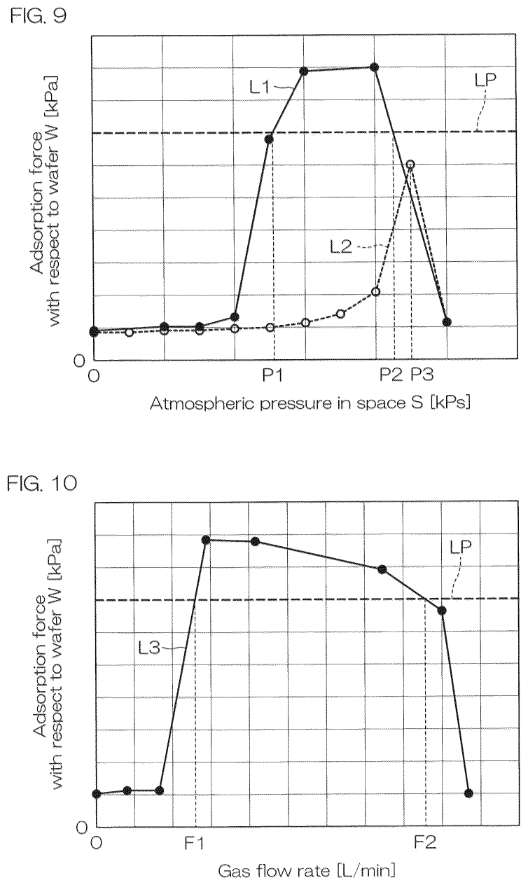

FIG. 9 is a graph showing a processing result of the warpage when the exhaust hole 36 is closed and when barometric pressure control is applied. In FIG. 9, the vertical axis represents an adsorption force [kPa] of the wafer W with respect to the support portion 25, and the horizontal axis represents atmospheric pressure [kPa] in the space S. Herein, a suction force given to the suction groove 31 is fixed at a predetermined value.

A first polygonal line L1, a second polygonal line L2, and a processable line LP (see broken line) are shown in FIG. 9. The first polygonal line L1 shows a result when an Si single crystal wafer W is employed. The second polygonal line L2 shows a result when a high-hard wafer W (SiC single crystal wafer W) is employed. The processable line LP shows a line according to which a series of processing steps are performed without allowing the wafer W to drop off from the support stage 20A.

Referring to the first polygonal line L1, when the wafer W was the Si single crystal wafer W, the adsorption force of the wafer W with respect to the support portion 25 increased in proportion to an increase in atmospheric pressure of the space S. This denotes that the adsorption force with respect to this wafer W increased in proportion to an increase in the amount of correction of the warpage of the Si single crystal wafer W. The adsorption force with respect to the wafer W exceeded the processable line LP in a range in which the atmospheric pressure of the space S is between the first atmospheric pressure P1 and the second atmospheric pressure P2 (P1<P2). On the other hand, the adsorption force with respect to the wafer W rapidly decreased when the atmospheric pressure of the space S exceeded the second atmospheric pressure P2. In other words, a force pushing up the Si single crystal wafer W exceeded the suction force, and, as a result, the wafer W dropped off from the support portion 25.

Referring to the second polygonal line L2, when the wafer W was the high-hard wafer W, the adsorption force of the wafer W with respect to the support portion 25 increased in proportion to an increase in atmospheric pressure of the space S. This denotes that the adsorption force with respect to this wafer W increased in proportion to an increase in the amount of correction of the warpage of the high-hard wafer W. However, the adsorption force with respect to the wafer W did not exceed the processable line LP even if the atmospheric pressure of the space S was raised to the third atmospheric pressure P3 (P2<P3) that is higher than the second atmospheric pressure P2. The adsorption force with respect to the wafer W rapidly decreased when the atmospheric pressure of the space S exceeded the third atmospheric pressure P3. In other words, in the high-hard wafer W, a force pushing up the wafer W exceeded the suction force before correcting the warpage, and the wafer W dropped off from the support portion 25.

The atmospheric pressure of the space S rises if the exhaust hole 36 is closed. In other words, in barometric pressure control, a force that pushes up the wafer W is generated in the whole of a region, which faces the first plate surface 22, of the second main surface 2 of the wafer W. The Si single crystal wafer W has comparatively low hardness, and is deformable. Therefore, the warpage of the Si single crystal wafer W is corrected by comparatively low atmospheric pressure. On the other hand, the high-hard wafer W has higher hardness than the Si single crystal wafer W, and is less deformable. Therefore, the warpage of the high-hard wafer W is corrected by atmospheric pressure that is higher than atmospheric pressure applied to the Si single crystal wafer W.

However, in the high-hard wafer W, the additional value of both the atmospheric pressure and the pressing force resulting from an ejected gas will exceed the suction force before correcting the warpage if the atmospheric pressure is excessively raised, and, as a result, the wafer W drops off from the support stage 20A. In the high-hard wafer W, it is also conceivable that the suction force (adsorption force) given from the suction groove 31 to the wafer W will be raised, and, in accordance with this, measures to raise the atmospheric pressure will be taken. However, in this case, an excessive load is imposed onto the high-hard wafer W, and therefore this is not preferable. Therefore, in barometric pressure control according to the high-hard wafer W, advanced control is required for balance among the atmospheric pressure, the pressing force, and the suction force, unlike barometric pressure control according to the Si single crystal wafer W.

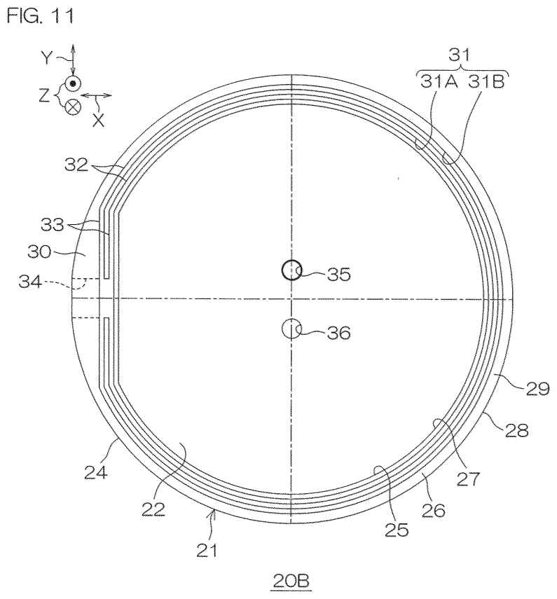

FIG. 10 is a graph showing a processing result of the warpage when the exhaust hole 36 is opened and when barometric pressure control is not applied. In FIG. 10, the vertical axis represents an adsorption force [kPa] of the wafer W with respect to the support portion 25, and the horizontal axis represents a flow rate [L/min] of a gas ejected from the ejecting hole 35. Herein, a suction force given to the suction groove 31 is fixed at a predetermined value in the same way as in the barometric pressure control (see FIG. 9). A third polygonal line L3 and the aforementioned processable line LP are shown in FIG. 10. The third polygonal line L3 shows a result when a high-hard wafer W (SiC single crystal wafer W) is employed.

Referring to the third polygonal line L3, the adsorption force of the high-hard wafer W with respect to the support portion 25 increased in proportion to an increase in flow rate of the ejected gas. This denotes that the adsorption force with respect to the high-hard wafer W increased in proportion to an increase in the amount of correction of the warpage of this high-hard wafer W. The adsorption force of the wafer W exceeded the processable line LP in a range in which the flow rate of the ejected gas is between the first flow rate F1 and the second flow rate F2 (F1<F2). The first flow rate F1 is a value exceeding 0 L/min. On the other hand, the adsorption force of the wafer W rapidly decreased when the flow rate of the ejected gas exceeded the second flow rate F2. In other words, a force pushing up the high-hard wafer W exceeded the suction force, and, as a result, the wafer W dropped off from the support portion 25.

If the exhaust hole 36 is opened, the pressing force by which the warpage is corrected is given from the ejected gas to the wafer W. On the other hand, a rise in the atmospheric pressure of the space S is restrained. Particularly in this embodiment, the ejected gas is locally sprayed onto a place at which the warpage of the wafer W starts as a starting point (in this embodiment, an inward portion of the wafer W). In other words, the suction force (adsorption force) with respect to the wafer W is given in the peripheral edge portion of the wafer W, while the pressing force that corrects the warpage of the wafer W in the inward portion of the wafer W is locally given.

Therefore, it is possible to restrain the occurrence of a force pushing up the wafer W in a wide area of the second main surface 2 of the wafer W, thereby making it possible to correct the warpage of the wafer W while preventing the wafer W from dropping off from the support portion 25. Also, the warpage of the wafer W is corrected by the flow control of the ejected gas, and therefore advanced control is not required in comparison with barometric pressure control. Also, a contact portion of the ejected gas with respect to the wafer W is local, thereby making it possible to reduce a load imposed on the wafer W.

As described above, the support stage 20A includes the base portion 21, the support portion 25, the suction groove 31, the ejecting hole 35, and the exhaust hole 36. The support portion 25 is configured to be erected at the peripheral edge portion of the base portion 21 and to come into contact with the second main surface 2 (support surface) of the wafer W. The suction groove 31 is configured to be provided at the support portion 25 and is configured so that the suction force is to be given to the second main surface 2. The ejecting hole 35 is configured to be provided in the inward portion of the base portion 21 and is configured so that a gas is to be ejected toward the second main surface 2. The exhaust hole 36 is configured to be provided in at least one of the base portion 21 and the support portion 25 (in this embodiment, base portion 21) and is configured to discharge a gas from the space S between the base portion 21, the support portion 25, and the support surface. This structure makes it possible to provide the support stage 20A capable of correcting the warpage of the wafer W. The support stage 20A is effective to correct the warpage of the wafer W by the gas flow control.

FIG. 11 is a plan view showing a support stage 20B according to a second embodiment. The support stage 20B is a jig that is to be applied to the support device 40 and that fulfills the same effect as the support stage 20A. Referring to FIG. 11, the support stage 20B includes the ejecting hole 35 provided at a distance from the center of the first plate surface 22 to one side in the second direction Y. In other words, the ejecting hole 35 is arranged at a distance from the center of the first plate surface 22 in the extending direction of the linear contact portion 30 (orientation flat of the wafer W).

The support stage 20B includes the exhaust hole 36 provided at a distance from the center of the first plate surface 22 on the other side in the second direction Y. In other words, the exhaust hole 36 is arranged at a distance from the center of the first plate surface 22 in a direction in which the linear contact portion 30 extends. In other words, if a line perpendicular to the linear contact portion 30 is set, the exhaust hole 36 is placed on this line together with the ejecting hole 35.

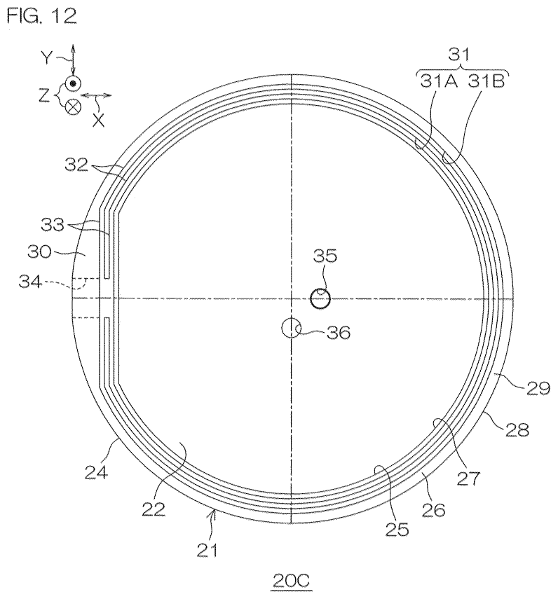

FIG. 12 is a plan view showing a support stage 20C according to a third embodiment. The support stage 20C is a jig that is to be applied to the support device 40 and that fulfills the same effect as the support stage 20A. Referring to FIG. 12, the support stage 20C includes the ejecting hole 35 that is provided at a distance from the center of the first plate surface 22 in either one of the first direction X and the second direction Y (in this embodiment, first direction X). In other words, the ejecting hole 35 is arranged at a distance from the center of the first plate surface 22 in a direction perpendicular to the extending direction of the linear contact portion 30. Also, if a first line perpendicular to the linear contact portion 30 is set so as to pass through the center of the first plate surface 22, the ejecting hole 35 is placed on this first line together with the center of the first plate surface 22.

The support stage 20C includes the exhaust hole 36 provided at a distance from the center of the first plate surface 22 in a direction (in this embodiment, second direction Y) differing from that of the ejecting hole 35. The exhaust hole 36 is arranged at a distance from the center of the first plate surface 22 in a direction in which the linear contact portion 30 extends. If a second line perpendicular to the first line so as to pass through the center of the first plate surface 22, the exhaust hole 36 is placed on this second line together with the center of the first plate surface 22.

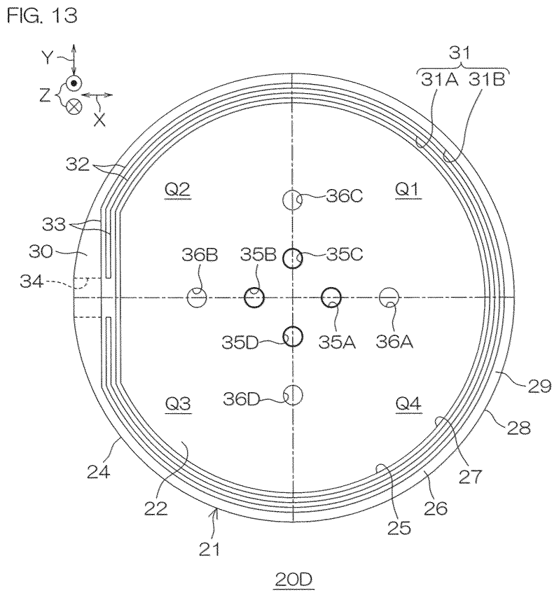

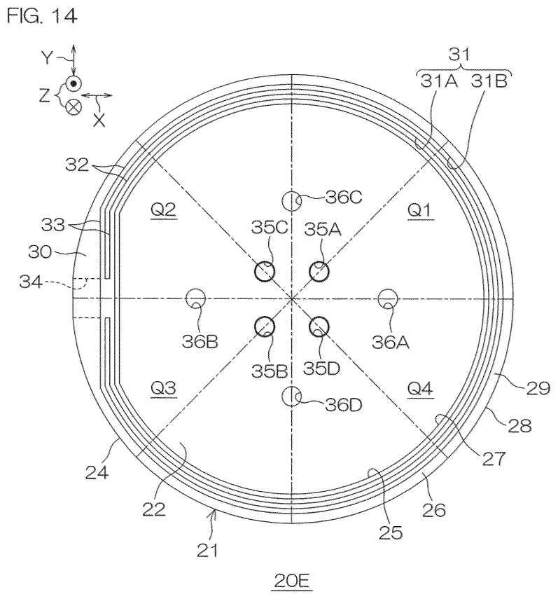

FIG. 13 is a plan view showing a support stage 20D according to a fourth embodiment. The support stage 20D is a jig that is to be applied to the support device 40 and that fulfills the same effect as the support stage 20A. Referring to FIG. 13, the support stage 20C includes the plurality of ejecting holes 35 that are provided in the first plate surface 22 in this embodiment. The plurality of ejecting holes 35 are provided at a distance from the center of the first plate surface 22 in either one or both of the first direction X and the second direction Y. Preferably, the plurality of ejecting holes 35 are each arranged at a position at which a distance from the center of the base portion 21 becomes less than a distance from the support portion 25 in the same way as in the first embodiment.

In this embodiment, the plurality of ejecting holes 35 include first to fourth ejecting holes 35A to 35D. The first and second ejecting holes 35A and 35B are provided at a distance from the center of the first plate surface 22 on one side and the other side in the first direction X, and face each other in the first direction X across the center of the first plate surface 22. The third and fourth ejecting holes 35C and 35D are provided at a distance from the center of the first plate surface 22 on one side and the other side in the second direction Y, and face each other in the second direction Y across the center of the first plate surface 22. Preferably, the plurality of ejecting holes 35 are placed on a concentric circle surrounding the center of the first plate surface 22.

In this embodiment, the support stage 20D includes the plurality of exhaust holes 36 that are provided at the first plate surface 22. The plurality of exhaust holes 36 are provided at a distance from the center of the first plate surface 22 in either one or both of the first direction X and the second direction Y. Preferably, the plurality of exhaust holes 36 are arranged at a position at which a distance from the center of the base portion 21 becomes less than a distance from the support portion 25 in the same way as in the first embodiment.

In this embodiment, the plurality of exhaust holes 36 include first to fourth exhaust holes 36A to 36D. The first and second exhaust holes 36A and 36B are provided at a distance from the center of the first plate surface 22 on one side and the other side in the first direction X, and face each other in the first direction X across the center of the first plate surface 22. In this embodiment, the first and second exhaust holes 36A and 36B are each arranged so as to interpose the first and second ejecting holes 35A and 35B between the first and second exhaust holes 36A and 36B from both sides in the first direction X.

The third and fourth exhaust holes 36C and 36D are provided at a distance from the center of the first plate surface 22 on one side and the other side in the second direction Y, and face each other in the second direction Y across the center of the first plate surface 22. In this embodiment, the third and fourth exhaust holes 36C and 36D are each arranged so as to interpose the third and fourth ejecting holes 35C and 35D between the third and fourth exhaust holes 36C and 36D from both sides in the second direction Y. Preferably, the plurality of exhaust holes 36 are placed on a concentric circle surrounding the center of the first plate surface 22.

FIG. 14 is a plan view showing a support stage 20E according to a fifth embodiment. The support stage 20E is a jig that is to be applied to the support device 40 and that fulfills the same effect as the support stage 20A. Referring to FIG. 14, the support stage 20E has a structure in which the arrangement of the plurality of ejecting holes 35 has been changed in the support stage 20D (see FIG. 13).

In this embodiment, the first and second ejecting holes 35A and 35B are provided at a distance from the center of the first plate surface 22 on one side and the other side of a direction intersecting the first and second directions X and Y. If a crossline passing through the center of the first plate surface 22 is set so as to divide the first plate surface 22 into the first to fourth quadrants Q1 to Q4, the first and second ejecting holes 35A and 35B are placed at the first quadrant Q1 and the third quadrant Q3 of the first plate surface 22, respectively. In this embodiment, the first and second ejecting holes 35A and 35B are each arranged on a line that is inclined by +450 with respect to the first direction X, and face each other across the center of the first plate surface 22.

In this embodiment, the third and fourth ejecting holes 35C and 35D are provided at a distance from the center of the first plate surface 22 on one side and the other side of a direction intersecting the first and second directions X and Y. If the aforementioned crossline is set, the third and fourth ejecting holes 35C and 35D are placed at a second quadrant Q2 and a fourth quadrant Q4 of the first plate surface 22, respectively.

In this embodiment, the third and fourth ejecting holes 35C and 35D are each arranged on a line that is inclined by −45° with respect to the first direction X, and face each other across the center of the first plate surface 22. Also, in this embodiment, the third and fourth ejecting holes 35C and 35D are arranged at positions at which the third and fourth ejecting holes 35C and 35D face the first and second ejecting holes 35A and 35B in the first and second directions X and Y, respectively. Preferably, the plurality of ejecting holes 35 are placed on a concentric circle surrounding the center of the first plate surface 22 in the same way as in the case of the support stage 20D (see FIG. 13).

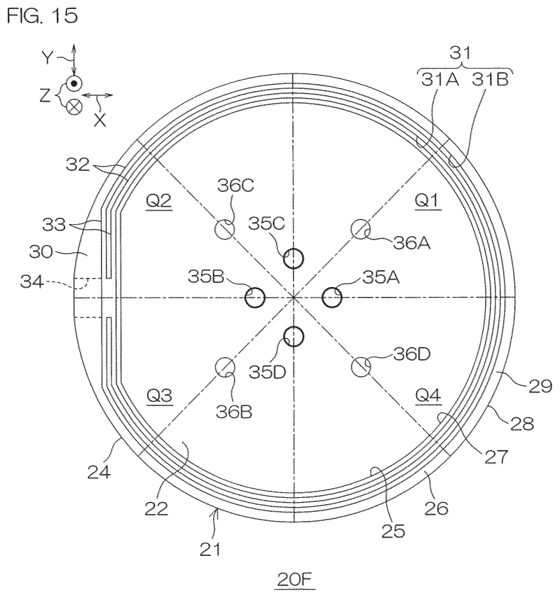

FIG. 15 is a plan view showing a support stage 20F according to a sixth embodiment. The support stage 20F is a jig that is to be applied to the support device 40 and that fulfills the same effect as the support stage 20A. Referring to FIG. 15, the support stage 20F has a structure in which the arrangement of the plurality of exhaust holes 36 has been changed in the support stage 20D (see FIG. 13).

In this embodiment, the first and second exhaust holes 36A and 36B are provided at a distance from the center of the first plate surface 22 on one side and the other side in a direction intersecting the first and second directions X and Y. If a crossline passing through the center of the first plate surface 22 is set so as to divide the first plate surface 22 into the first to fourth quadrants Q1 to Q4, the first and second exhaust holes 36A and 36B are placed at the first quadrant Q1 and the third quadrant Q3 of the first plate surface 22, respectively.

In this embodiment, the first and second exhaust holes 36A and 36B are each arranged on a line that is inclined by +45° with respect to the first direction X, and face each other across the center of the first plate surface 22. In this embodiment, the first and second exhaust holes 36A and 36B are arranged at positions at which the first and second exhaust holes 36A and 36B do not face the plurality of ejecting holes 35 in the first and second directions X and Y, respectively.

In this embodiment, the third and fourth exhaust holes 36C and 36D are provided at a distance from the center of the first plate surface 22 on one side and the other side in a direction intersecting the first and second directions X and Y. If the aforementioned crossline is set, the third and fourth exhaust holes 36C and 36D are placed at the second quadrant Q2 and the fourth quadrant Q4 of the first plate surface 22, respectively. In this embodiment, the third and fourth exhaust holes 36C and 36D are each arranged on a line that is inclined by −45° with respect to the first direction X, and face each other across the center of the first plate surface 22.

Also, in this embodiment, the third and fourth exhaust holes 36C and 36D are arranged at positions at which the third and fourth exhaust holes 36C and 36D face the first and second exhaust holes 36A and 36B in the first and second directions X and Y, respectively. In this embodiment, the third and fourth exhaust holes 36C and 36D are arranged at positions at which the third and fourth exhaust holes 36C and 36D do not face the plurality of ejecting holes 35 in the first and second directions X and Y, respectively. Preferably, the plurality of exhaust holes 36 are placed on a concentric circle surrounding the center of the first plate surface 22 in the same way as in the case of the support stage 20D (see FIG. 13).

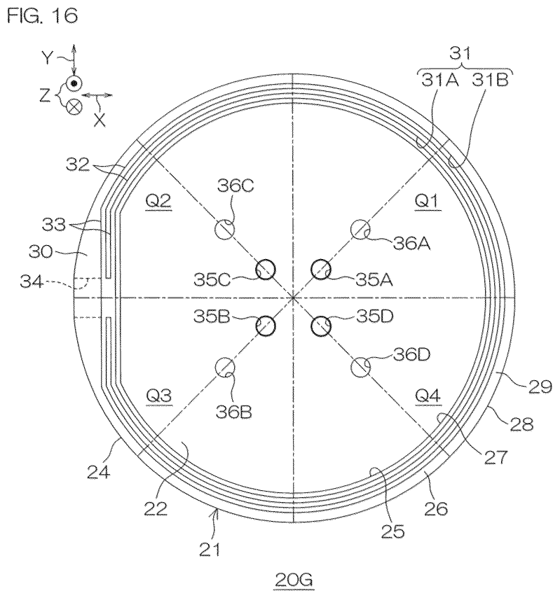

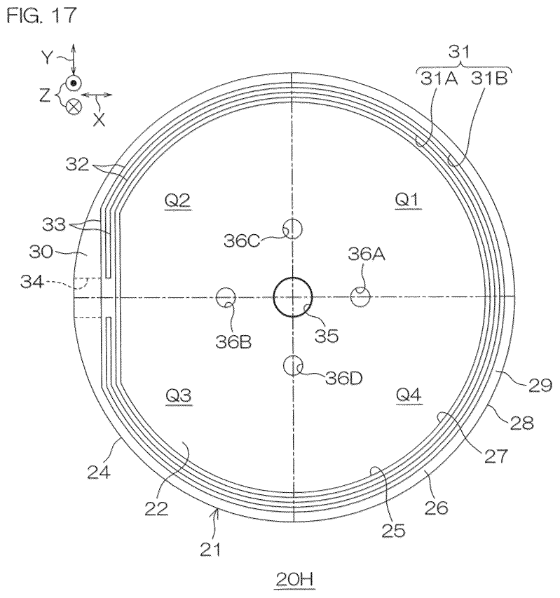

FIG. 16 is a plan view showing a support stage 20G according to a seventh embodiment. The support stage 20G is a jig that is to be applied to the support device 40 and that fulfills the same effect as the support stage 20A. Referring to FIG. 16, the support stage 20G has a structure in which the support stage 20E (see FIG. 14) according to the fifth embodiment and the support stage 20F (see FIG. 15) according to the sixth embodiment have been combined together.

In other words, the first and second exhaust holes 36A and 36B are arranged at the first quadrant Q1 and the third quadrant Q3 together with the first and second ejecting holes 35A and 35B, respectively, and are placed on the same line as the first and second ejecting holes 35A and 35B. Also, the third and fourth exhaust holes 36C and 36D are arranged at the second quadrant Q2 and the fourth quadrant Q4 together with the third and fourth ejecting holes 35C and 35D, respectively, and are placed on the same line as the third and fourth ejecting holes 35C and 35D.

Preferably, the plurality of ejecting holes 35 are placed on a concentric circle surrounding the center of the first plate surface 22 in the same way as in the case of the support stage 20D (see FIG. 13). Also, preferably, the plurality of exhaust holes 36 are placed on a concentric circle surrounding the center of the first plate surface 22 in the same way as in the case of the support stage 20D (see FIG. 13).

FIG. 17 is a plan view showing a support stage 20H according to an eighth embodiment. The support stage 20H is a jig that is to be applied to the support device 40 and that fulfills the same effect as the support stage 20A. Referring to FIG. 17, the support stage 20H includes the single ejecting hole 35 placed at the central portion of the first plate surface 22. In this embodiment, the ejecting hole 35 is provided at a position at which the ejecting hole 35 coincides with the center of the first plate surface 22.

The support stage 20H includes the plurality of exhaust holes 36 (plurality of exhaust holes 36A to 36D) placed at the central portion of the first plate surface 22. The plurality of exhaust holes 36 each have a width less than the width of the ejecting hole 35. The arrangement place of the plurality of exhaust holes 36 is optional. The plurality of exhaust holes 36 may be arranged by the same layout as the layout of the plurality of exhaust holes 36 according to the support stages 20D to 20H (see FIG. 13 to FIG. 17). In other words, the plurality of exhaust holes 36 may be provided at a distance from the ejecting hole 35 in the first and second directions X and Y, or may be provided at a distance from the ejecting hole 35 in a direction intersecting the first and second directions X and Y.

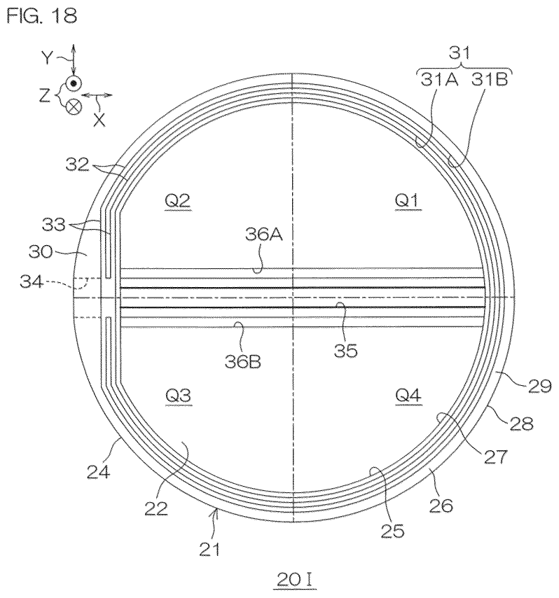

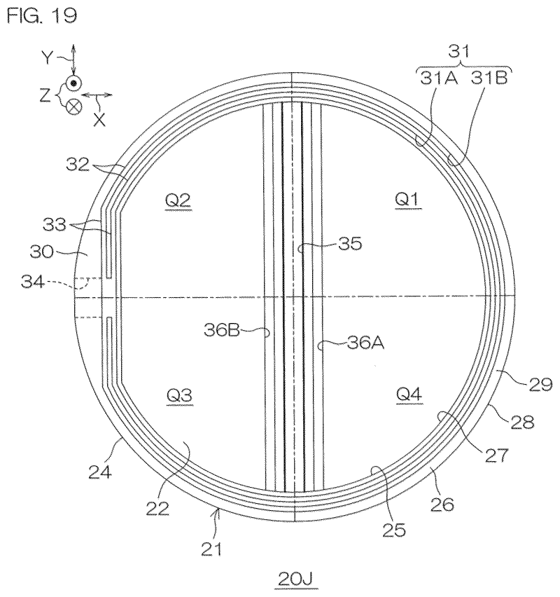

FIG. 18 is a plan view showing a support stage 20I according to a ninth embodiment. The support stage 20I is a jig that is to be applied to the support device 40 and that fulfills the same effect as the support stage 20A. Referring to FIG. 18, in this embodiment, the support stage 20I includes at least one (in this embodiment, one) ejecting hole 35 that extends in a belt shape in the first direction X in the central portion of the first plate surface 22. In this embodiment, the ejecting hole 35 extends in a direction perpendicular to the extending direction of the linear contact portion 30 (orientation flat of the wafer W) so as to pass through the center of the first plate surface 22. The ejecting hole 35 may be provided at a distance from the support portion 25, or may be continuous with the support portion 25.

In this embodiment, the support stage 20I includes at least one (in this embodiment, a plurality of) exhaust hole 36 arranged at a distance from the ejecting hole 35 in the second direction Y. In this embodiment, the plurality of exhaust holes 36 include the first exhaust hole 36A and the second exhaust hole 36B. The first exhaust hole 36A is provided at a distance from the ejecting hole 35 on one side in the second direction Y. The second exhaust hole 36B is provided at a distance from the ejecting hole 35 on the other side in the second direction Y. The second exhaust hole 36B faces the first exhaust hole 36A across the ejecting hole 35. Preferably, the width of each of the plurality of exhaust holes 36 is less than the width of the ejecting hole 35. The plurality of exhaust holes 36 may be provided at a distance from the support portion 25, or may be continuous with the support portion 25.

The planar shape of the plurality of exhaust holes 36 is optional. In this embodiment, the plurality of exhaust holes 36 are each formed in a belt shape extending along the ejecting hole 35. The plurality of exhaust holes 36 may be formed in a circular shape or a polygonal shape in a plan view. The plurality of exhaust holes 36 may include the plurality of first exhaust holes 36A and the plurality of second exhaust holes 36B arranged with intervals therebetween along the ejecting hole 35.

FIG. 19 is a plan view showing a support stage 20J according to a tenth embodiment. The support stage 20J is a jig that is to be applied to the support device 40 and that fulfills the same effect as the support stage 20A. Referring to FIG. 19, in this embodiment, the support stage 20J includes at least one (in this embodiment, one) ejecting hole 35 that extends in a belt shape in the second direction Y in the central portion of the first plate surface 22. In this embodiment, the ejecting hole 35 extends in the extending direction of the linear contact portion 30 (orientation flat of the wafer W) so as to pass through the center of the first plate surface 22. The ejecting hole 35 may be provided at a distance from the support portion 25, or may be continuous with the support portion 25.

In this embodiment, the support stage 20J includes at least one (in this embodiment, a plurality of) exhaust hole 36 arranged at a distance from the ejecting hole 35 in the second direction Y. In this embodiment, the plurality of exhaust holes 36 include the first exhaust hole 36A and the second exhaust hole 36B. The first exhaust hole 36A is provided at a distance from the ejecting hole 35 on one side in the first direction X. The second exhaust hole 36B is provided at a distance from the ejecting hole 35 on the other side in the first direction X. The second exhaust hole 36B faces the first exhaust hole 36A across the ejecting hole 35.

Preferably, the width of each of the plurality of exhaust holes 36 is less than the width of the ejecting hole 35. The plurality of exhaust holes 36 may be provided at a distance from the support portion 25, and may be continuous with the support portion 25. The planar shape of the plurality of exhaust holes 36 is optional. In this embodiment, the plurality of exhaust holes 36 are each formed in a belt shape extending along the ejecting hole 35. The plurality of exhaust holes 36 may be each formed in a circular shape or a polygonal shape in a plan view. The plurality of exhaust holes 36 may include the plurality of first exhaust holes 36A arranged at a distance along the ejecting hole 35 and the plurality of second exhaust holes 36B.

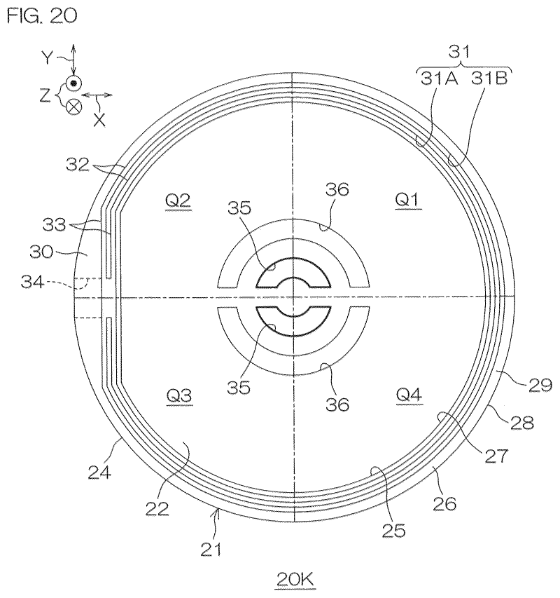

FIG. 20 is a plan view showing a support stage 20K according to an eleventh embodiment. The support stage 20K is a jig that is to be applied to the support device 40 and that fulfills the same effect as the support stage 20A. Referring to FIG. 20, in this embodiment, the support stage 20K includes at least one (in this embodiment, a plurality of) ejecting hole 35 that extends in a circular-arc belt shape in the central portion of the first plate surface 22. The plurality of ejecting holes 35 are each provided in a circular-arc belt shape extending along the peripheral edge of the base portion 21 so as to surround the center of the first plate surface 22 at a distance from the center of the first plate surface 22. Particularly preferably, the plurality of ejecting holes 35 are provided on a concentric circle surrounding the center of the first plate surface 22.

In this embodiment, the support stage 20K includes at least one (in this embodiment, a plurality of) exhaust hole 36 that extends in a circular-arc belt shape in the central portion of the first plate surface 22. The plurality of exhaust holes 36 are each provided in a circular-arc belt shape extending along the ejecting hole 35 (peripheral edge of the base portion 21) at a distance from the plurality of ejecting holes 35. The plurality of exhaust holes 36 are provided so as to surround the plurality of ejecting holes 35. Particularly preferably, the plurality of exhaust holes 36 are provided on a concentric circle surrounding the center of the first plate surface 22.

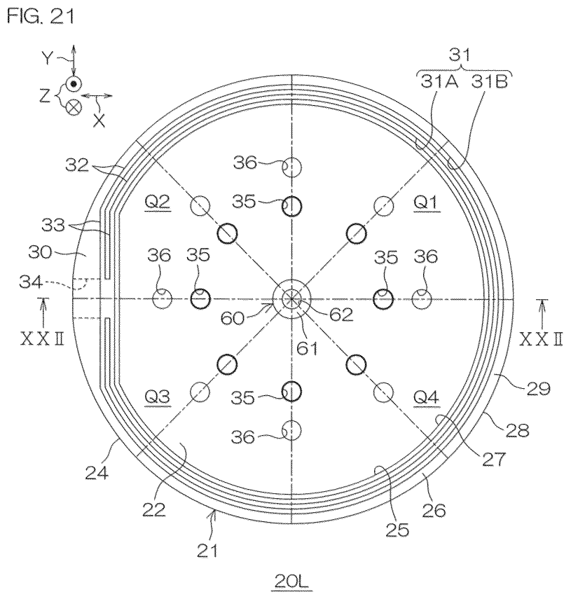

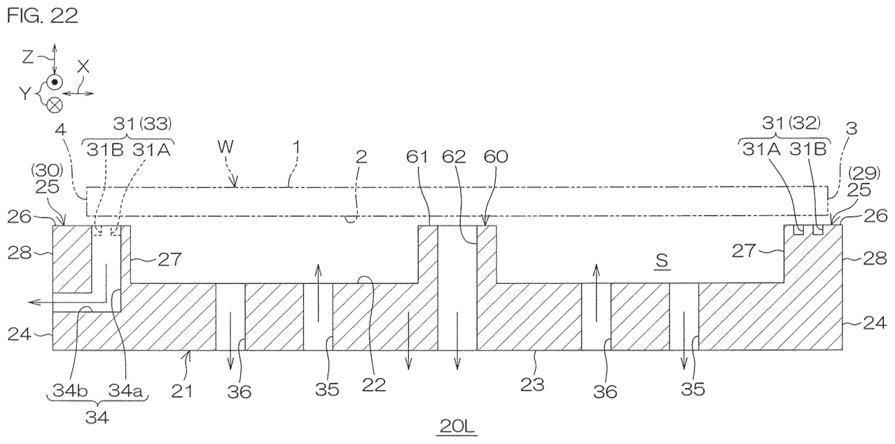

FIG. 21 is a plan view showing a support stage 20L according to a twelfth embodiment. FIG. 22 is a cross-sectional view along line XXII-XXII shown in FIG. 21. The support stage 20L is a jig that is to be applied to the support device 40 and that fulfills the same effect as the support stage 20A. Referring to FIG. 21 and FIG. 22, in this embodiment, the support stage 20L includes a metallic inner support portion 60 erected at the inward portion of the first plate surface 22 in the base portion 21. The inner support portion 60 may be made of stainless steel (for example, SUS303, SUS304, or the like).

The inner support portion 60 is a portion with which the second main surface 2 of the wafer W is to be come into contact in the first plate surface 22 that is more inward than the support portion 25. In this embodiment, the inner support portion 60 is formed integrally with the base portion 21. The inner support portion 60 is configured to is to be come into contact with an inward portion of the second main surface 2 and to support the wafer W in a state of being away from the first plate surface 22 (base portion 21). In this embodiment, the inner support portion 60 is erected in a pillar shape (in this embodiment, circular cylindrical shape) at a position at which the inner support portion 60 coincides with the center of the first plate surface 22. The inner support portion 60 may be formed in a polygonal cylindrical shape. The inner support portion 60 defines an annular recess (in this embodiment, circular annular recess) with the first plate surface 22 and with the support portion 25 in the inward portion of the base portion 21.

The inner support portion 60 has an inner contact surface 61 with which the second main surface 2 is to be come into contact. Preferably, the inner contact surface 61 is a flat surface that extends in parallel with the second main surface 2. Preferably, the width of the inner support portion 60 falls within a range of not less than 1 mm and not more than 50 mm. In this embodiment, the width of the inner support portion 60 is defined by the length of a chord passing through the center of the inner support portion 60.

The support stage 20L includes at least one inner suction hole 62 provided in the inner support portion 60. In detail, the inner suction hole 62 is configured so that the inner suction hole 62 passes through the base portion 21 and the inner support portion 60 in the vertical direction Z and so that a suction force from the inner support portion 60 side toward the base portion 21 side is given from the outside. The inner suction hole 62 is configured so that the suction force (adsorption force) is given to the second main surface 2 in a state in which the second main surface 2 is in contact with the inner suction hole 62. In this embodiment, the inner suction hole 62 is formed in a circular shape in a plan view. The inner suction hole 62 may be formed in a polygonal shape in a plan view. Preferably, the width of the inner suction hole 62 falls within a range of not less than 1 mm and not more than 45 mm. In this embodiment, the width of the inner suction hole 62 is defined by the length of a chord passing through the center of the inner suction hole 62.

In this embodiment, the support stage 20L includes at least one (in this embodiment, a plurality of) ejecting hole 35 provided at a distance from the support portion 25 and from the inner support portion 60 in a region between the support portion 25 and the inner support portion 60 in the first plate surface 22. The shape, the number, and the arrangement of the ejecting hole 35 are optional. The ejecting hole 35 may be arranged by the same layout as the layout of the ejecting hole 35 according to the support stages 20A to 20O (see FIG. 3 to FIG. 21). The ejecting hole 35 may be arranged by a layout obtained by combining at least two layouts among the layouts of the ejecting hole 35 according to the support stages 20A to 20O together (see FIG. 3 to FIG. 21).

In this embodiment, the support stage 20L includes at least one (in this embodiment, a plurality of) exhaust hole 36 provided at a distance from the ejecting hole 35, from the support portion 25, and from the inner support portion 60 in a region between the support portion 25 and the inner support portion 60 in the first plate surface 22. The shape, the number, and the arrangement of the exhaust hole 36 are optional. The exhaust hole 36 may be arranged by the same layout as the layout of the exhaust hole 36 according to the support stage 20A to 20O (see FIG. 3 to FIG. 21). The exhaust hole 36 may be arranged by a layout obtained by combining at least two layouts among the layouts of the exhaust hole 36 according to the support stages 20A to 20O together (see FIG. 3 to FIG. 21).

If the support stage 20L is applied to the support device 40, the support device 40 may have the suction unit 41 connected to the support portion 25 and to the inner support portion 60. Of course, the support device 40 may include a first suction unit 41 connected to the support portion 25 and a second suction unit 41 connected to the inner support portion 60.

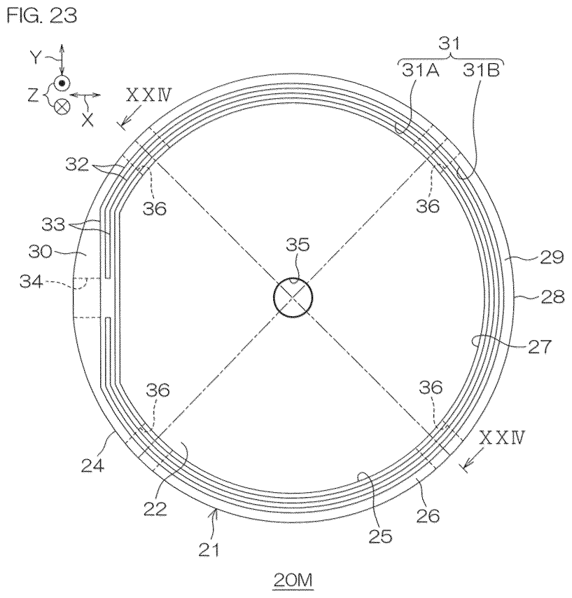

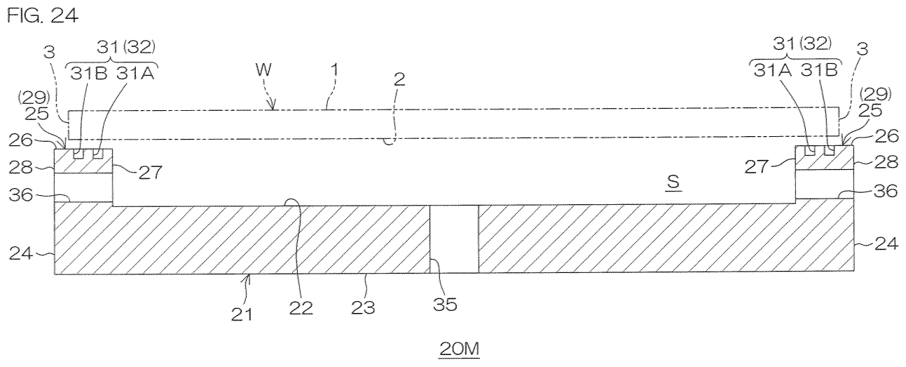

FIG. 23 is a plan view showing a support stage 20M according to a thirteenth embodiment. FIG. 24 is a cross-sectional view along line XXIV-XXIV shown in FIG. 23. The support stage 20M is a jig that is to be applied to the support device 40 and that fulfills the same effect as the support stage 20A. Referring to FIG. 23 and FIG. 24, in this embodiment, the support stage 20M includes at least one (in this embodiment, four) exhaust hole 36 provided in the support portion 25. The exhaust hole 36 according to this embodiment may be referred to as a “peripheral exhaust hole.”

The plurality of exhaust holes 36 are each provided at a thickness position away from the suction groove 31 in the support portion 25, and pass through the inner wall 27 and the outer wall 28 of the support portion 25. A part of each of the exhaust holes 36 may be placed in the base portion 21. The shape, the number, and the arrangement of each of the exhaust holes 36 are optional. A structure in which the exhaust hole 36 is provided in the support portion 25 may be applied to the support stages 20A to 20P (see FIG. 3 to FIG. 22).

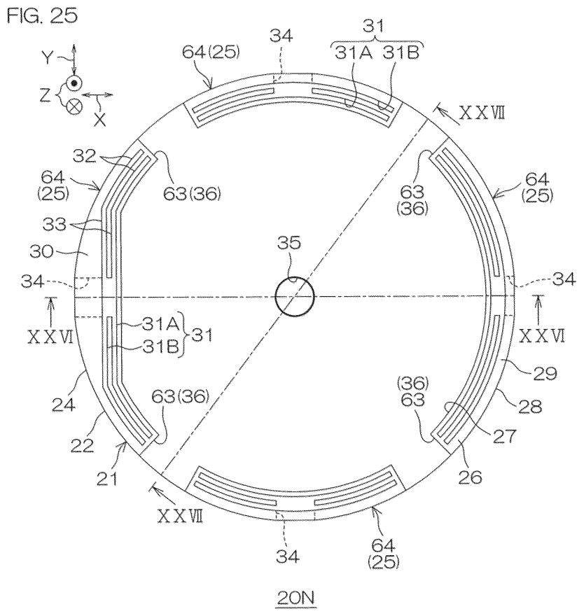

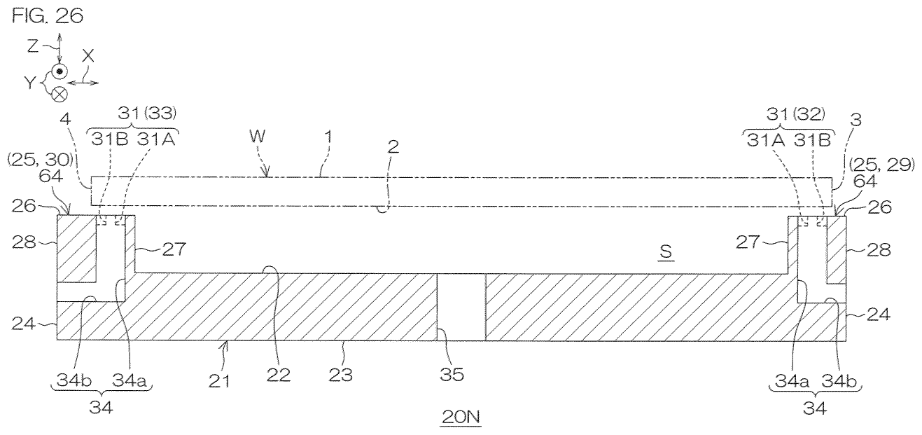

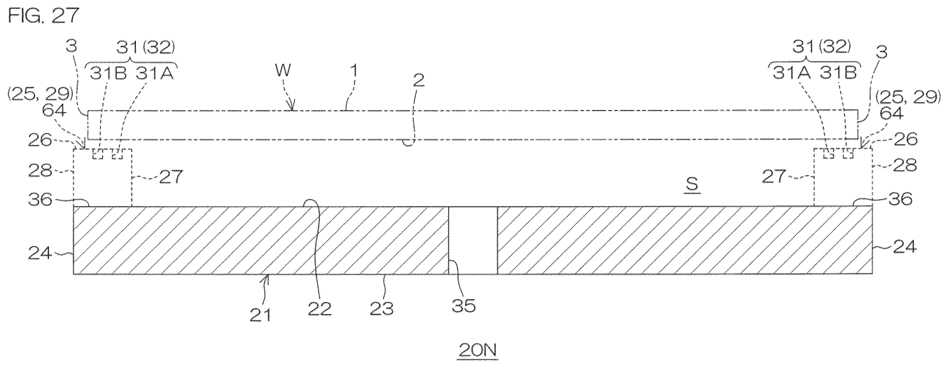

FIG. 25 is a plan view showing a support stage 20N according to a fourteenth embodiment. FIG. 26 is a cross-sectional view along line XXVI-XXVI shown in FIG. 25. FIG. 27 is a cross-sectional view along line XXVII-XXVII shown in FIG. 25. The support stage 20N is a jig that is to be applied to the support device 40 and that fulfills the same effect as the support stage 20A. Referring to FIG. 25 to FIG. 27, in this embodiment, the support stage 20N includes the support portion 25 erected in a circular-arc belt shape in the peripheral edge portion of the base portion 21.

In detail, the support portion 25 includes at least one segment support portion 64 divisionally formed in an ended belt shape by at least one slit 63 in the peripheral edge portion of the base portion 21. In other words, in this embodiment, the support portion 25 has a configuration that supports the wafer W by at least one segment support portion 64. In this embodiment, the support portion 25 includes a plurality of (in this embodiment, four) segment support portions 64 divisionally formed in an ended belt shape by a plurality of (in this embodiment, four) slits 63, respectively.

The plurality of slits 63 are each formed in a circular-arc shape extending along a peripheral edge of the base end portion in a plan view, and the plurality of segment support portions 64 are each formed in a circular-arc belt shape extending along the peripheral edge of the base end portion in a plan view. The number, the position, and the magnitude of the slit 63 are optional, and the number, the position, and the magnitude of the segment support portion 64 are optional.

The suction groove 31 and the suction hole 34 mentioned above are each provided in each of the segment support portions 64. Each of the suction grooves 31 is provided at the contact surface 26 of each of the segment support portions 64 at a distance from a peripheral edge of each of the segment support portions 64. Each of the suction grooves 31 extends in a circular-arc belt shape in each of the segment support portions 64. Each of the suction holes 34 has a first hole 34a and a second hole 34b communicating with each of the suction grooves 31 in each of the segment support portions 64.

In this embodiment, the exhaust hole 36 mentioned above is formed by the slit 63 of the support portion 25. The exhaust hole 36 according to this embodiment may be referred to as a “peripheral exhaust hole.” If the support stage 20N is applied to the support device 40, the support device 40 may have the single suction unit 41 connected to the plurality of suction holes 34. Of course, the support device 40 may have the plurality of suction units 41 respectively connected to the plurality of suction holes 34 so as to individually control the suction force of the plurality of suction holes 34 (suction grooves 31).

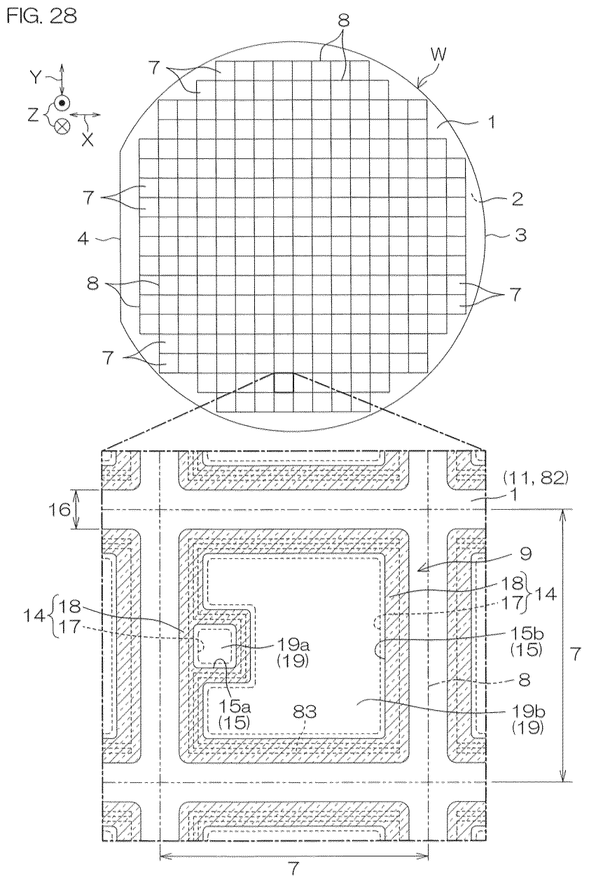

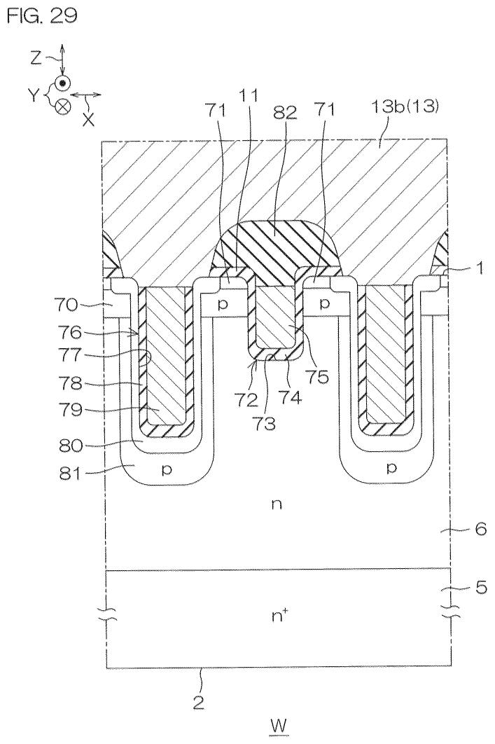

Other configuration examples of the wafer W will be hereinafter described. FIG. 28 is a plan view showing another configuration example of the wafer W shown in FIG. 1. FIG. 29 is an enlarged cross-sectional view of a main portion of the functional device 9 shown in FIG. 28. Referring to FIG. 28 and FIG. 29, in this embodiment, the functional device 9 includes MISFET (Metal Insulator Semiconductor Field Effect Transistor) instead of SBD. In this embodiment, the MISFET is a trench gate type MISFET. A structure of the single functional device 9 (device region 7) will be hereinafter described.

The wafer W includes a p-type body region 70 formed in the surface layer portion of the first main surface 1 in the device region 7. The body region 70 is formed in the surface layer portion of the second region 6 at a distance from a bottom portion of the second region 6 toward the first main surface 1 side. The wafer W includes an n-type source region 71 formed in a surface layer portion of the body region 70. The source region 71 has an n-type impurity concentration higher than the second region 6. The source region 71 forms a channel between the second region 6 and the MISFET in the body region 70.

The wafer W includes a plurality of trench gate structures 72 formed in the first main surface 1 in the device region 7. The plurality of trench gate structures 72 control an inversion and a non-inversion of the channel. The plurality of trench gate structures 72 pass through the body region 70 and the source region 71, and reach the second region 6. The plurality of trench gate structures 72 may be arranged at a distance from each other in the first direction X in a plan view, and may be each formed in a belt shape extending in the second direction Y.

Each of the trench gate structures 72 includes a gate trench 73, a gate insulating film 74, and a gate electrode 75. The gate trench 73 is formed in the first main surface 1. The gate insulating film 74 covers a wall surface of the gate trench 73. The gate electrode 75 is embedded in the gate trench 73 with the gate insulating film 74 between the gate electrode 75 and the gate trench 73. The gate electrode 75 faces the channel across the gate insulating film 74.

The wafer W includes a plurality of trench source structures 76 formed in the first main surface 1 in the device region 7. The plurality of trench source structures 76 are each arranged in a region between two adjacent trench gate structures 72 in the first main surface 1. The plurality of trench source structures 76 may be each formed in a belt shape extending in the second direction Y in a plan view. The plurality of trench source structures 76 pass through the body region 70 and the source region 71, and reach the second region 6. The plurality of trench source structures 76 have a depth exceeding the depth of the trench gate structure 72.

Each of the trench source structures 76 includes a source trench 77, a source insulating film 78, and a source electrode 79. The source trench 77 is formed in the first main surface 1. The source insulating film 78 covers a wall surface of the source trench 77. The source electrode 79 is embedded in the source trench 77 with the source insulating film 78 between the source electrode 79 and the source trench 77.

The wafer W includes a plurality of p-type contact regions 80 formed in regions along the plurality of trench source structures 76 in the device region 7, respectively. The plurality of contact regions 80 have a p-type impurity concentration higher than the body region 70. Each of the contact regions 80 covers a sidewall and a bottom wall of each of the trench source structures 76, and is electrically connected to the body region 70.

The wafer W includes a plurality of p-type well regions 81 formed in regions along the plurality of trench source structures 76, respectively, in the device region 7. Each of the well regions 81 has a p-type impurity concentration that is higher than the body region 70 and that is lower than the contact region 80. Each of the well regions 81 covers a corresponding one of the trench source structures 76 across a corresponding one of the contact regions 80. Each of the well regions 81 covers the sidewall and the bottom wall of a corresponding one of the trench source structures 76, and is electrically connected to the body region 70.

The wafer W includes the aforementioned main surface insulating film 11 covering the first main surface 1 in the device region 7. The main surface insulating film 11 is continuous with the gate insulating film 74 and with the source insulating film 78, and exposes the gate electrode 75 and the source electrode 79. In this embodiment, the main surface insulating film 11 covers the peripheral edge portion of the device region 7 (boundary portion of the plurality of device regions 7). Of course, the main surface insulating film 11 may expose the peripheral edge portion of the device region 7 (boundary portion of the plurality of device regions 7).

The wafer W includes an interlayer insulating film 82 covering the main surface insulating film 11 in the device region 7. The interlayer insulating film 82 may include at least one among a silicon oxide film, a silicon nitride film, and a silicon oxynitride film. The interlayer insulating film 82 covers the plurality of trench gate structures 72 and the plurality of trench source structures 76. The interlayer insulating film 82 may cover the peripheral edge portion of the device region 7 (boundary portion of the plurality of device regions 7) across the main surface insulating film 11. Of course, the main surface insulating film 11 may expose the first main surface 1 or the main surface insulating film 11 in the peripheral edge portion of the device region 7 (boundary portion of the plurality of device regions 7).

The wafer W includes the aforementioned plurality of first main surface electrodes 13 covering the interlayer insulating film 82 in the device region 7. The plurality of first main surface electrodes 13 may have a layered structure including a Ti-based metal film and an Al-based metal film. In this embodiment, the plurality of first main surface electrodes 13 include a gate main surface electrode 13a and a source main surface electrode 13b. In this embodiment, the gate main surface electrode 13a is arranged in a region in proximity to a central portion of a side of the device region 7 in a plan view. The gate main surface electrode 13a may be arranged at a corner portion of the device region 7 in a plan view. In this embodiment, the gate main surface electrode 13a is formed in a quadrangular shape in a plan view.

The source main surface electrode 13b is arranged on the interlayer insulating film 82 at a distance from the gate main surface electrode 13a. In this embodiment, the source main surface electrode 13b is formed in a polygonal shape having a concave portion hollowed along the gate main surface electrode 13a in a plan view. The source main surface electrode 13b may be formed in a quadrangular shape in a plan view. The source main surface electrode 13b passes through the interlayer insulating film 82 and through the main surface insulating film 11, and is electrically connected to the plurality of trench source structures 76, to the source region 71, and to the plurality of well regions 81.

The wafer W includes a gate wiring electrode 83 pulled out from the gate main surface electrode 13a onto the interlayer insulating film 82 in the device region 7. The gate wiring electrode 83 may have a layered structure including a Ti-based metal film and an Al-based metal film in the same way as the plurality of first main surface electrodes 13. The gate wiring electrode 83 is formed in a belt shape extending along the peripheral edge of the device region 7 so as to intersect (in detail, perpendicularly intersect) an end portion of the plurality of trench gate structures 72 in a plan view. The gate wiring electrode 83 passes through the interlayer insulating film 82, and is electrically connected to the plurality of trench gate structures 72.

The wafer W includes the aforementioned insulating film 14 covering the plurality of first main surface electrodes 13 in the device region 7. The insulating film 14 has a layered structure including the inorganic insulating film 17 and the organic insulating film 18 stacked together in this order from the first main surface electrode 13 side. In this embodiment, the insulating film 14 covers a peripheral edge portion of the gate main surface electrode 13a and a peripheral edge portion of the source main surface electrode 13b at a distance inwardly from the peripheral edge of the device region 7. The insulating film 14 covers the whole area of the gate wiring electrode 83.

The insulating film 14 defines the plurality of pad openings 15 that expose an inward portion of the gate main surface electrode 13a and an inward portion of the source main surface electrode 13b in the inward portion of the device region 7, and defines the street opening 16 that exposes either one or both of the main surface insulating film 11 and the interlayer insulating film 82 in the peripheral edge portion of the device region 7. The street opening 16 may expose the first main surface 1.

In this embodiment, the plurality of pad openings 15 include a gate pad opening 15a that exposes the inward portion of the gate main surface electrode 13a and a source pad opening 15b that exposes the inward portion of the source main surface electrode 13b. In this embodiment, the gate pad opening 15a is divisionally formed in a quadrangular shape along the peripheral edge of the gate main surface electrode 13a in a plan view. In this embodiment, the source pad opening 15b is formed in a polygonal shape along the peripheral edge of the source main surface electrode 13b in a plan view.

The organic insulating film 18 may cover the inorganic insulating film 17 so as to expose either one or both of the inner peripheral portion and the outer peripheral portion of the inorganic insulating film 17. In this embodiment, the organic insulating film 18 exposes both of the inner peripheral portion and the outer peripheral portion of the inorganic insulating film 17, and defines the inorganic insulating film 17, the plurality of pad openings 15, and the street opening 16. The organic insulating film 18 may cover the whole area of the inorganic insulating film 17.

The wafer W includes the aforementioned plurality of pad electrodes 19 covering the plurality of first main surface electrodes 13, respectively, in the device region 7. In this embodiment, the plurality of pad electrodes 19 include a gate pad electrode 19a and a source pad electrode 19b. The gate pad electrode 19a is arranged in the gate pad opening 15a, and covers the inward portion of the gate main surface electrode 13a. The gate pad electrode 19a has a gate electrode 75 surface placed in the gate pad opening 15a, and is not arranged outside the gate pad opening 15a. The source pad electrode 19b is arranged in the source pad opening 15b, and covers the inward portion of the source main surface electrode 13b. The source pad electrode 19b has a source electrode 79 surface placed in the source pad opening 15b, and is not arranged outside the source pad opening 15b.

The presence or absence of both the insulating film 14 and the pad electrode 19 is optional. Therefore, a wafer W that has the insulating film 14 and that does not have the pad electrode 19 may be employed. Also, a wafer W that does not have the insulating film 14 and that has the pad electrode 19 may be employed. Also, a wafer W that does not have both the insulating film 14 and the pad electrode 19 may be employed.

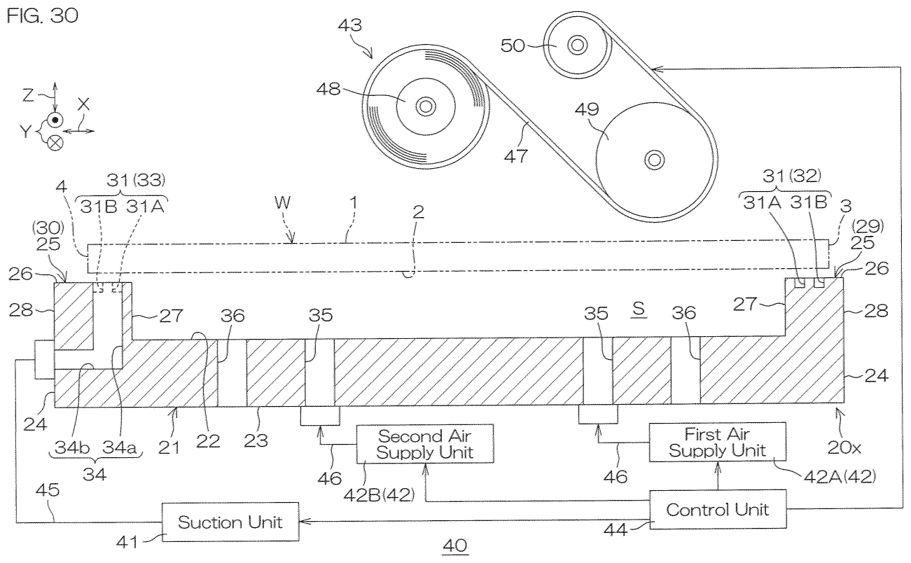

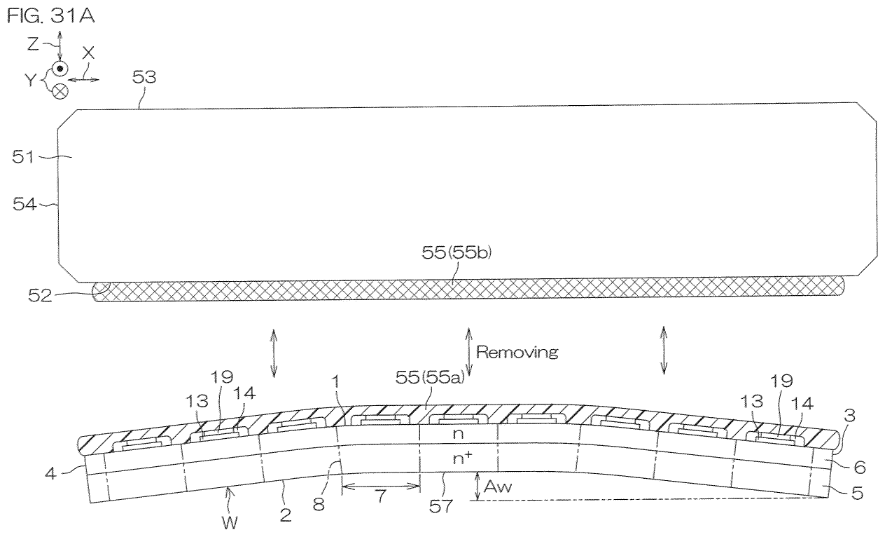

Another configuration example of the support device 40 will be hereinafter described. FIG. 30 is a plan view showing another configuration example of the support device 40 shown in FIG. 6. Referring to FIG. 30, if the support device 40 includes a support stage 20x having the plurality of ejecting holes 35, the support device 40 may have the plurality of gas supply units 42 connected to the plurality of ejecting holes 35, respectively, so as to individually control the flow rate (pressure) of a gas ejected from the plurality of ejecting holes 35.

The support stage 20x is a support stage having the plurality of ejecting holes 35 among the support stages 20A to 20N mentioned above. FIG. 30 shows an example in which the support device 40 includes a first gas supply unit 42A connected to at least one ejecting hole 35 and a second gas supply unit 42B connected to at least one ejecting hole 35.

The support stage 20x may include a first ejecting hole 35 provided for the warpage starting-point portion 57 extending along the first crystal axis of an SiC single crystal and a second ejecting hole 35 provided for the warpage starting-point portion 57 extending along the second crystal axis perpendicular to the first crystal axis of the SiC single crystal. Also, the first gas supply unit 42A may be connected to the first ejecting hole 35, and the second gas supply unit 42B may be connected to the second ejecting hole 35. If the thus formed structure is employed, it is possible to correct the warpage of the wafer W by controlling the first gas supply unit 42A and the second gas supply unit 42B in accordance with the structure (extending direction) of the warpage starting-point portion 57.

An example in which the support stages 20A to 20N (support device 40) are applied to the wafer W having the warpage that is in a valley-fold state has been shown in the aforementioned embodiment. However, whether a valley-fold-shaped warpage occurs in the wafer W or a mountain-fold-shaped warpage occurs in the wafer W depends on stress or the like caused by the thickness of the wafer W or caused by a structural component built into the wafer W. The manufacturing method of the semiconductor device that uses the support stages 20A to 20N (support device 40) is also applied to a wafer W having a mountain-fold-shaped warpage.

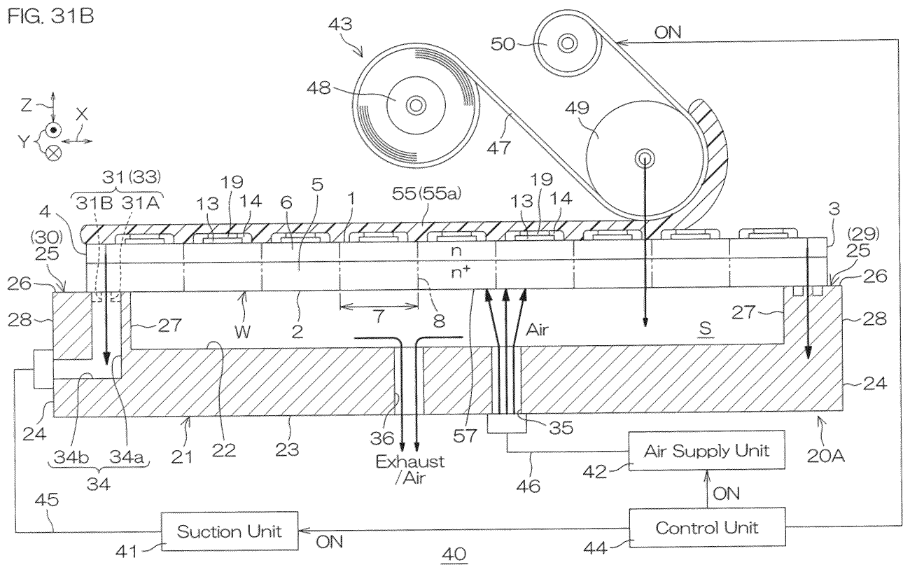

FIG. 31A and FIG. 31B are schematic views each of which shows an example of one step performed with respect to a wafer W having a mountain-fold-shaped warpage. An example in which the support stage 20A is applied to the support device 40 is hereinafter shown. The following steps may be performed in a state in which the second main surface electrode 58 has been formed on the second main surface 2 although an example in which the second main surface electrode 58 is not formed on the second main surface 2 is shown in the undermentioned description.

Referring to FIG. 31A, the wafer W that has been thinned and been released from the wafer support plate 51 through the steps of FIGS. 8A to 8E may have the warpage having the center of curvature on the second main surface 2 side. In other words, the wafer W may have a convexly curved warpage in which the height position of its central portion is placed at a relatively upward position with respect to the height position of its peripheral edge portion in a state in which the first main surface 1 is upwardly placed. The warpage of the wafer W occurs due to the stress of a structural component (for example, the first main surface electrode 13 or the like) on the first main surface 1 side.

In this case, the wafer W has the warpage starting-point portion 57 extending along the first crystal axis of the SiC single crystal with respect to the direction along the first main surface 1. In this embodiment, the warpage starting-point portion 57 is in a mountain-fold state. The warpage of the wafer W is formed in a mountain-fold shape in which the first main surface 1 (silicon surface) and the second main surface 2 (carbon surface) is inclined more downwardly in proportion to a retreat from the warpage starting-point portion 57 toward the second crystal axis side of the SiC single crystal perpendicular to the first crystal axis of the SiC single crystal. The first crystal axis may be the m-axial direction of the SiC single crystal, and the second crystal axis may be the a-axial direction of the SiC single crystal. The first crystal axis may be the a-axial direction of the SiC single crystal, and the second crystal axis may be the m-axial direction of the SiC single crystal. The wafer W may have an amount of warpage Aw of not less than 100 μm and not more than 10000 μm in the same way as in the aforementioned case.

Referring to FIG. 31B, the step of thinning the wafer W is completed, and then the wafer W having the foreign substance (in this embodiment, adhesive agent film 55a) adhering onto the first main surface 1 is carried into the support device 40 (Step S5 of FIG. 7). The wafer W is placed on the support stage 20A (Step S6 of FIG. 7) in a state in which the second main surface 2 is in contact with the support portion 25 of the support stage 20A. Thereafter, the suction unit 41 is controlled in an ON state, and a suction force is given to the suction groove 31. Thereby, a suction force toward the support stage 20A side is given from the suction groove 31 to the peripheral edge portion of the second main surface 2, and the wafer W is adsorbed and supported by the support portion 25.

The peripheral edge portion of the wafer W is placed on the contact surface 26 of the support portion 25, and the central portion of the wafer W is placed at a higher position than the height position of the peripheral edge portion of the wafer W on the basis of the first plate surface 22. Due to the warpage, the central portion of the wafer W has stress that is urged in a direction opposite to a sucking direction (i.e., urged in a direction away from the support portion 25). Therefore, a gap caused by this stress is formed between the second main surface 2 of the wafer W and the contact surface 26, and the adsorption of the second main surface 2 with respect to the contact surface 26 is in an insufficient state.

Thereafter, the step of correcting the warpage of the wafer W (Step S7 of FIG. 7) and the step of processing the first main surface 1 of the wafer W are performed (Step S8 of FIG. 7). The processing step of the first main surface 1 is performed in parallel with the step of correcting the warpage of the wafer W. In the processing step of the first main surface 1, a pressing force toward the base portion 21 is given to the wafer W, and a predetermined process is applied to the first main surface 1.

In this embodiment, the processing step includes a step of giving a pressing force, which is directed to the support stage 20A, to the wafer W by pressing the processing unit 43 to the first main surface 1. Also, the processing step includes a step of peeling off the adhesive agent film 55a from the first main surface 1 by the tape 47 while giving the pressing force to the wafer W. In the processing unit 43, the tensile force of the tape 47 with respect to the first main surface 1 is adjusted so as to be less than the pressing force with respect to the wafer W.

Therefore, a force having a direction in which the wafer W is deformed from the mountain-fold-shaped warpage to the valley-fold-shaped warpage is given to the wafer W while a processing operation is being performed by the processing unit 43. When an excessive pressing force is given from the processing unit 43 to the wafer W, the wafer W is deformed into the valley-fold-shaped warpage, and the adsorption force of the second main surface 2 with respect to the contact surface 26 becomes lower, and, as a result, there is a possibility that the wafer W will drop off from the support portion 25.

In the step of correcting the warpage of the wafer W, the gas supply unit 42 is controlled so as to be in an ON state in a state in which the exhaust hole 36 is open, and a gas having a flow rate (pressure) by which the warpage of the wafer W is corrected is supplied to the ejecting hole 35. The ejecting hole 35 ejects a gas having a flow rate (pressure), by which the warpage is corrected, toward the second main surface 2. In this embodiment, the ejected gas is brought into contact with the central portion of the second main surface 2. In detail, the ejected gas is brought into contact with the warpage starting-point portion 57 of the wafer W or with surroundings of the warpage starting-point portion 57.

Thereby, the pressing force (correcting force) in the direction away from the base portion 21 (first plate surface 22) is given to the central portion of the second main surface 2. In other words, in this step, the suction force having a direction toward the base portion 21 is given to the peripheral edge portion of the second main surface 2, and the pressing force having a direction away from the base portion 21 is given to the central portion of the second main surface 2 in a state in which the pressing force from the processing unit 43 toward the base portion 21 has been given to the wafer W.

In other words, in the step of correcting the warpage of the wafer W, a force having a direction in which the wafer W is deformed from the valley-fold-shaped warpage into the mountain-fold-shaped warpage (i.e., force having a direction opposite to the pressing force of the processing unit 43) is given to the wafer W. The flow rate (pressure) of a gas with respect to the wafer W is adjusted so that the warpage of the wafer W is corrected in a state in which the pressing force has been given from the processing unit 43 to the wafer W. Thereby, the warpage of the wafer W is restrained, and a gap between the second main surface 2 and the contact surface 26 is reduced, and, as a result, the adsorption force of the second main surface 2 with respect to the contact surface 26 becomes high. In this step, the warpage of the wafer W is corrected, thereby making it possible to apply an appropriate process to the first main surface 1. In other words, the reduction of the warpage makes it possible to appropriately peel off the adhesive agent film 55a from the first main surface 1.

Each of the embodiments mentioned above can be carried out in still other modes. For example, the wafer W has an orientation flat as an example of the mark 4 as described in each of the embodiments mentioned above. However, the wafer W may have an orientation notch as another example of the mark 4 instead of or in addition to the orientation flat. The orientation notch is a cutout portion that is hollowed into an arbitrary shape (for example, V shape) toward the central portion of the first main surface 1 in a plan view.

The orientation notch may be hollowed in the a-axial direction or in the m-axial direction. Of course, the mark 4 may include a first orientation notch that is hollowed in the a-axial direction and a second orientation notch that is hollowed in the m-axial direction. Preferably, the wafer W has a diameter equal to or more than 8 inches if the wafer W has an orientation notch. Also, preferably, the support stages 20A to 20N do not have the linear contact portion 30 if the wafer W having the orientation notch is placed on the support stages 20A to 20N.

In other words, preferably, the support stages 20A to 20N include the support portion 25 (at least one segment support portion 64) formed in a circular-arc shape or in an annular shape extending along the peripheral edge portion of the first plate surface 22 with a uniform width in a plan view. In this case, preferably, the support portion 25 is configured to coincide with the peripheral edge portion, which does not have the device region 7, of the wafer W in a plan view. Particularly preferably, the support portion 25 is configured not to coincide with the plurality of device regions 7 in a plan view.

In each of the embodiments mentioned above, a structure in which a relationship between the arrangement of the ejecting hole 35 and the arrangement of the exhaust hole 36 is replaced may be employed. A concrete configuration and a concrete description in this case can be obtained by replacing “the ejecting hole 35” with “the exhaust hole 36” and by replacing “the exhaust hole 36” with “the ejecting hole 35” in the description of each of the embodiments mentioned above and in the accompanying drawings.

The processing unit 43 is a tape transfer unit as described in the embodiment mentioned above. However, the process applied to the first main surface 1 in a state in which the warpage of the wafer W has been corrected is optional, and the processing unit 43 is not limited to the tape transfer unit. The processing unit 43 may be, for example, a fluid supply unit that supplies a fluid, such as a gas, a chemical liquid, or a solvent, to the first main surface 1 of the wafer W, or may be a film sticking unit that sticks a film onto the first main surface 1 of the wafer W.

The warpage of the wafer W including the SiC single crystal as an example of the wide bandgap semiconductor is corrected as described in each of the embodiments mentioned above. Of course, a wafer W including a wide bandgap semiconductor other than the SiC single crystal may be employed in each of the embodiments mentioned above. GaN (gallium nitride) or the like is mentioned as an example of the wide bandgap semiconductor other than the SiC single crystal. Also, the warpage of an Si single crystal wafer W may be corrected by the support device 40 to which the support stages 20A to 20N are applied. In this case, the warpage of the Si single crystal wafer W is corrected by a gas flow rate that is less than that of the high-hard wafer W.

The functional device 9 includes either one of SBD and MISFET as described in the embodiment mentioned above. However, the functional device 9 may include both of SBD and MISFET. In other words, both SBD and MISFET may be formed in the same device region 7.

The functional device 9 includes a trench gate type MISFET as described relative to the wafer W according to the other configuration examples. However, the functional device 9 may include a planar gate type MISFET instead of the trench gate type. Also, in the wafer W according to the other configuration examples, a p-type first region 5 may be employed instead of the n-type first region 5. In this case, the functional device 9 includes IGBT (Insulated Gate Bipolar Transistor) instead of MISFET. A concrete configuration in this case can be obtained by replacing the “source” of MISFET with the “emitter” of IGBT and by replacing the “drain” of MISFET with the “collector” of IGBT in the foregoing description.

An embodiment in which the first conductivity type is a p-type, and the second conductivity type is an n-type may be employed in the wafer W mentioned above. A concrete configuration in this case can be obtained by replacing the n-type region with the p-type region and by replacing the p-type region with the n-type region in the foregoing description and in the accompanying drawings.

Features extracted from this description and from the accompanying drawings are shown. A support stage capable of correcting the warpage of a wafer is hereinafter provided. Hereinafter, alphanumeric characters in parentheses represent corresponding components in the embodiments mentioned above, and yet this representation does not denote that the scope of each clause is limited to the embodiments.

[A1] A support stage (20A to 20N) comprising: a base portion (21); a support portion (25) that is erected at a peripheral edge portion of the base portion (21) and with which one surface (2) of a wafer (W) is to be come into contact; a suction groove (31) that is provided at the support portion (25) and to which a suction force with respect to the one surface (2) is to be given; an ejecting hole (35) that is provided in an inward portion of the base portion (21) and by which a gas is to be ejected toward the one surface (2); and an exhaust hole (36) that is provided in at least either one of the base portion (21) and the support portion (25) and by which a gas is to be discharged from a space (S) between the base portion (21), the support portion (25), and the one surface (2).

[A2] The support stage according to A1 (20A to 20N), wherein the support portion (25) is configured so that the one surface (2) of the wafer (W) having a warpage is to be come into contact with the support portion (25), and the ejecting hole (35) is configured to eject a gas having pressure by which the warpage of the wafer (W) is to be corrected, and the exhaust hole (36) is configured so that a rise in atmospheric pressure of the space (S) is to be restrained.

[A3] The support stage (20A to 20N) according to A1 or A2, wherein the wafer (W) is a high-hard wafer (W) having hardness that exceeds hardness of an Si single crystal.

[A4] The support stage (20A to 20N) according to any one of A1 to A3, wherein the wafer (W) is a wide bandgap semiconductor wafer having a bandgap that exceeds a bandgap of Si.

[A5] The support stage (20A to 20N) according to any one of A1 to A4, wherein the wafer (W) is an SiC wafer including an SiC single crystal.

[A6] The support stage (20A to 20N) according to any one of A1 to A5, wherein the support portion (25) is configured so that a peripheral edge portion of the one surface (2) of the wafer (W) is to be come into contact with the support portion (25).

[A7] The support stage (20A to 20N) according to any one of A1 to A6, wherein the support portion (25) is erected in an annular shape surrounding the inward portion of the base portion (21), and the ejecting hole (35) is provided in a region surrounded by the support portion (25) in the inward portion of the base portion (21).

[A8] The support stage (20A to 20N) according to A7, wherein the suction groove (31) extends in a belt shape along the support portion (25).

[A9] The support stage (20A to 20N) according to any one of A1 to A8, wherein the ejecting hole (35) is configured so that a gas is to be ejected toward a central portion of the one surface (2).

[A10] The support stage (20A to 20N) according to any one of A1 to A9, wherein the ejecting hole (35) is provided in a central portion of the base portion (21).

[A11] The support stage (20A to 20N) according to any one of A1 to A10, wherein the exhaust hole (36) is provided so as to adjoin the ejecting hole (35) in the inward portion of the base portion (21).

[A12] The support stage (20A to 20N) according to any one of A1 to A11, wherein the support portion (25) has a side that extends linearly along an orientation flat (4) of the wafer (W), and has a linear contact portion (30) that is to be come into contact with the orientation flat (4).

[A13] The support stage (20A to 20N) according to A12, wherein the suction groove (31) has a part that extends linearly along the linear contact portion (30).

[A14] The support stage (20A to 20N) according to any one of A1 to A13, wherein the suction groove (31) includes a first suction groove (31A) provided on an inward side of the base portion (21) and a second suction groove (31B) provided on a peripheral side of the base portion (21).

[A15] The support stage (20A to 20N) according to A14, wherein the first suction groove (31A) extends in a belt shape, and the second suction groove (31B) extends in a belt shape along the first suction groove (31A).

[A16] The support stage (20A to 20N) according to any one of A1 to A15, wherein the ejecting hole (35) is provided as a plurality of ejecting holes (35) arrayed along an arbitrary crystal orientation (a-axial direction and/or m-axial direction) of the wafer (W).

[A17] The support stage (20A to 20N) according to any one of A1 to A16, wherein the exhaust hole (36) is provided as a plurality of exhaust holes (36) arrayed along an arbitrary crystal orientation (a-axial direction and/or m-axial direction) of the wafer (W).

[A18] The support stage (20A to 20N) according to any one of A1 to A17, wherein the wafer (W) has the other surface (1) that is placed on a side opposite to the one surface (2) and in which a plurality of device regions (7) are arrayed.

[A19] The support stage (20A to 20N) according to A18, wherein the ejecting hole (35) is provided as a plurality of ejecting holes (35) arrayed along an array direction of the plurality of device regions (7).

[A20] The support stage (20A to 20N) according to A18 to A19, wherein the exhaust hole (36) is provided as a plurality of exhaust holes (36) arrayed along the array direction of the plurality of device regions (7).

[A21] A support device (40) comprising: the support stage (20A to 20N) according to any one of A1 to A20; a suction unit (41) that is connected to the suction groove (31) and by which a suction force is to be given to the suction groove (31); and a gas supply unit (42) that is connected to the ejecting hole (35) and by which a gas is to be supplied to the ejecting hole (35).

[A22] A method for manufacturing a semiconductor device using the support device (40) according to A21, the method comprising: a step of allowing the support portion (25) to adsorb the one surface (2) of the wafer (W); and a step of ejecting a gas from the ejecting hole (35) toward the one surface (2) in a state in which the exhaust hole (36) is opened.

[A23] The method for manufacturing the semiconductor device according to A22, wherein the wafer (W) having a warpage is prepared, and the support portion (25) is allowed to adsorb a peripheral edge portion of the one surface (2) of the wafer, and a gas having pressure by which the warpage of the wafer (W) is corrected is ejected from the ejecting hole (35) toward the one surface (2).

[A24] The method for manufacturing the semiconductor device according to A22 or A23, further comprising: a processing step of applying a predetermined process onto the other surface (1) of the wafer (W) in a state in which a gas is ejected from the ejecting hole (35).

[A25] The method for manufacturing the semiconductor device according to A24, wherein the wafer (W) having a foreign substance that have adhered to the other surface (1) is prepared, and the processing step includes a step of removing the foreign substance (55) from the other surface (1).

Although the embodiments have been described in detail, these embodiments are merely concrete examples used to clarify the technical contents, and the present invention should not be interpreted by being limited to these specific examples, and the scope of the present invention is limited by the appended claims.

What is claimed is:

1. A support stage comprising:
a base portion;
a support portion that is erected at a peripheral edge portion of the base portion and with which one surface of a wafer is to be come into contact;
a suction groove that is provided at the support portion and to which a suction force with respect to the one surface is to be given;
an ejecting hole that is provided in an inward portion of the base portion and by which a gas is to be ejected toward the one surface; and
an exhaust hole that is provided in at least either one of the base portion and the support portion and by which a gas is to be discharged from a space between the base portion, the support portion, and the one surface.

2. The support stage according to claim 1,
wherein the support portion is configured so that the one surface of the wafer having a warpage is to be come into contact with the support portion, and
the ejecting hole is configured to eject a gas having pressure by which the warpage of the wafer is to be corrected, and
the exhaust hole is configured so that a rise in atmospheric pressure of the space is to be restrained.

3. The support stage according to claim 1,
wherein the wafer is a high-hard wafer having hardness that exceeds hardness of an Si single crystal.

4. The support stage according to claim 1,
wherein the wafer is a wide bandgap semiconductor wafer having a bandgap that exceeds a bandgap of Si.

5. The support stage according to claim 1,
wherein the wafer is an SiC wafer including an SiC single crystal.

6. The support stage according to claim 1,
wherein the support portion is configured so that a peripheral edge portion of the one surface of the wafer is to be come into contact with the support portion.

7. The support stage according to claim 1,
wherein the support portion is erected in an annular shape surrounding the inward portion of the base portion, and
the ejecting hole is provided in a region surrounded by the support portion in the inward portion of the base portion.

8. The support stage according to claim 7,
wherein the suction groove extends in a belt shape along the support portion.

9. The support stage according to claim 1,
wherein the ejecting hole is configured so that a gas is to be ejected toward a central portion of the one surface.

10. The support stage according to claim 1,
wherein the ejecting hole is provided in a central portion of the base portion.

11. The support stage according to claim 1,
wherein the exhaust hole is provided so as to adjoin the ejecting hole in the inward portion of the base portion.

12. The support stage according to claim 1,
wherein the support portion has a side that extends linearly along an orientation flat of the wafer, and has a linear contact portion that is to be come into contact with the orientation flat.

13. The support stage according to claim 12,
wherein the suction groove has a part that extends linearly along the linear contact portion.

14. The support stage according to claim 1,
wherein the suction groove includes a first suction groove provided on an inward side of the base portion and a second suction groove provided on a peripheral side of the base portion.

15. The support stage according to claim 14,
wherein the first suction groove extends in a belt shape, and
the second suction groove extends in a belt shape along the first suction groove.

16. A support device comprising:
the support stage according to claim 1;
a suction unit that is connected to the suction groove and by which a suction force is to be given to the suction groove; and
a gas supply unit that is connected to the ejecting hole and by which a gas is to be supplied to the ejecting hole.

17. A method for manufacturing a semiconductor device using the support device according to claim 16, the method comprising:
a step of allowing the support portion to adsorb the one surface of the wafer; and
a step of ejecting a gas from the ejecting hole toward the one surface in a state in which the exhaust hole is opened.

18. The method for manufacturing the semiconductor device according to claim 17,
wherein the wafer having a warpage is prepared, and
the support portion is allowed to adsorb a peripheral edge portion of the one surface of the wafer, and
a gas having pressure by which the warpage of the wafer is corrected is ejected from the ejecting hole toward the one surface.

19. The method for manufacturing the semiconductor device according to claim 17, further comprising:
a processing step of applying a predetermined process onto the other surface of the wafer in a state in which a gas is ejected from the ejecting hole.

20. The method for manufacturing the semiconductor device according to claim 19,
wherein the wafer having a foreign substance adhered to the other surface is prepared, and
the processing step includes a step of removing the foreign substance from the other surface.
